(19) United States
(12) Patent Application Publication
(10) Pub. No.: US 2024/0339500 A1
(43) Pub. Date: Oct. 10, 2024

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventor: Katsumi NAKAMURA, Tokyo (JP)

(73) Assignee: Mitsubishi Electric Corporation, Tokyo (JP)

(21) Appl. No.: 18/487,022

(22) Filed: Oct. 13, 2023

(30) Foreign Application Priority Data
Apr. 7, 2023 (JP) 2023-062638

(51) Int. Cl. H01L 29/08; H01L 21/265; H01L 29/66; H01L 29/739

(52) U.S. Cl. CPC H01L 29/0821; H01L 21/2652; H01L 29/083; H01L 29/6609; H01L 29/66348; H01L 29/7397; H01L 29/868

(57) ABSTRACT

According to an aspect of the present disclosure, a semiconductor device includes a silicon substrate having a first surface and a second surface opposite the first surface and containing oxygen as impurity, a first electrode provided on the first surface and a second electrode provided on the second surface, wherein the silicon substrate includes an n type drift layer having impurity concentration that is higher on the second surface side, an n type first buffer layer provided on the second surface side of the drift layer and containing protons as impurity, and a second buffer layer provided on the second surface side of the first buffer layer.

### BACKGROUND

### Field

The present disclosure relates to a semiconductor device and a method of manufacturing the semiconductor device.

### Background

JP 2008-91853 A discloses an insulated gate bipolar transistor (IGBT) in which the impurity concentration of an N− drift layer has a local maximum at at least one place. The impurity concentration of the N− drift layer decreases in directions toward a P base layer and a P collector layer from the place where the impurity concentration has a local maximum. Furthermore, oxygen atoms and elements lighter than oxygen are contained at least at the place where the impurity concentration of the N− drift layer has a local maximum.

In JP 2008-91853 A, a floating zone (FZ) wafer is used as a Si wafer. In Patent Literature 1, with proton irradiation, protons are introduced into Si from an emitter electrode side on which a metal-oxide-semiconductor (MOS) transistor of an IGBT is formed, and accordingly, the impurity profile of a drift layer is formed. Thus, protons that are charged particles pass through a MOS transistor area. Thus, degradation of MOS transistor characteristics and characteristics of a gate oxide film included in a MOS gate structure potentially occurs.

### SUMMARY

The present disclosure is made to solve the above-described problem and intended to obtain a semiconductor device and a method of manufacturing a semiconductor device that can reduce degradation of characteristics.

The features and advantages of the present disclosure may be summarized as follows.

According to an aspect of the present disclosure, a semiconductor device includes a silicon substrate having a first surface and a second surface opposite the first surface and containing oxygen as impurity, a first electrode provided on the first surface and a second electrode provided on the second surface, wherein the silicon substrate includes an n type drift layer having impurity concentration that is higher on the second surface side, an n type first buffer layer provided on the second surface side of the drift layer and containing protons as impurity, and a second buffer layer provided on the second surface side of the first buffer layer.

According to an aspect of the present disclosure, a method of manufacturing a semiconductor device includes forming a semiconductor layer on a first surface side of a silicon wafer manufactured by an MCZ method and including an n type drift layer, forming a second buffer layer by performing ion implantation into a second surface opposite the first surface of the silicon wafer and performing annealing, implanting protons to a position deeper than the second buffer layer with respect to the second surface after the second buffer layer is formed and forming a first buffer layer by performing annealing for the protons after the protons are implanted.

Other and further objects, features and advantages of the disclosure will appear more fully from the following description.

### BRIEF DESCRIPTION OF DRAWINGS

FIG. 1 is a plan view of a semiconductor device according to a first embodiment.

FIG. 2A is a cross-sectional view of an IGBT according to the first embodiment.

FIG. 2B is a cross-sectional view of a diode according to the first embodiment.

FIG. 2C is a cross-sectional view illustrating another example of a diode according to the first embodiment.

FIG. 3A is a diagram illustrating the impurity profile of the drift layer according to the first embodiment.

FIG. 3B is a diagram for description of influence of the buffer layer on the impurity profile of the drift layer.

FIG. 3C is a calculation result of the impurity profile of hydrogen concentration in the depth direction.

FIG. 4 is a diagram illustrating the relation between the change amount of the impurity concentration of the drift layer and voltage resistance.

FIG. 5 is a diagram illustrating the relation between the oxygen concentration and the impurity concentration of the drift layer in an MCZ wafer.

FIG. 6 is a diagram illustrating measured temperature dependency of static voltage resistance for a 3.3 kV diode.

FIG. 7 is a diagram illustrating test results of a safe operating area in a dynamic state for the 3.3 kV IGBT and diode.

FIG. 8 is a diagram illustrating waveforms of RBSOA.

FIG. 9 is a diagram illustrating waveforms of SCSOA.

FIG. 10 is a diagram illustrating waveforms of recovery SOA.

FIG. 11A is a diagram illustrating an impurity profile according to a second embodiment.

FIG. 11B is a diagram illustrating various impurity profiles of the first buffer layer.

FIG. 11C is a diagram illustrating the impurity profile of the first buffer layer according to a modification of the second embodiment.

FIG. 12 is a diagram illustrating the waveform of the 1200V diode at voltage resistance holding.

FIG. 13 is a diagram illustrating device characteristics of the 1200V diode.

FIG. 14 is a diagram illustrating the waveform of RBSOA.

FIG. 15 is a diagram illustrating the waveform of Recovery SOA.

FIGS. 16A to 16M are diagrams for description of the method of manufacturing the IGBT according to a third embodiment.

FIG. 17 is a flowchart illustrating a method of forming the vertical structure according to the third embodiment.

FIGS. 18A to 18I are diagrams for description of a method of manufacturing the diode according to a fourth embodiment.

FIG. 19 is a flowchart illustrating the method of forming the vertical structure according to the fourth embodiment.

FIG. 20 is a flowchart illustrating a method of forming the vertical structure according to a modification of the fourth embodiment.

FIGS. 21 to 28 are cross-sectional views illustrating examples of the semiconductor device according to a fifth embodiment.

### DESCRIPTION OF EMBODIMENTS

A semiconductor device and a method of manufacturing the semiconductor device according to each embodiment will be described with reference to the accompanying drawings. Components identical or corresponding to each other are indicated by the same reference characters, and repeated description of them is avoided in some cases.

### First Embodiment

FIG. 1 is a plan view of a semiconductor device 100 according to a first embodiment. The semiconductor device 100 is, for example, a power semiconductor chip. An active cell area 1 is an area that guarantees basic performance of the power semiconductor chip. An interface area 2 is an area in which the active cell area 1 is joined to an edge termination area 3. The interface area 2 supports the breakdown resistance amount of the power semiconductor in dynamic operation and supports the original performance of the active cell area 1. The edge termination area 3 is provided to hold voltage resistance in a static state and guarantee the stability and reliability of voltage resistance characteristics. The edge termination area 3 further reduces degradation of the breakdown resistance amount in dynamic operation and supports the original performance of the active cell area 1.

With the above-described areas, it is possible to improve total loss performance, improve leakage characteristics in voltage holding at high temperature, guarantee reliability, improve controllability in dynamic operation, and guarantee the breakdown resistance amount. A total loss includes a loss in an “on” state, a loss in a turn-on state, and a loss in a turn-off state. The semiconductor device 100 includes a front surface gate wire portion 4 and a gate pad portion 39. The front surface gate wire portion 4 and the gate pad portion 39 are not provided in some cases in which the semiconductor device 100 is a diode, for example.

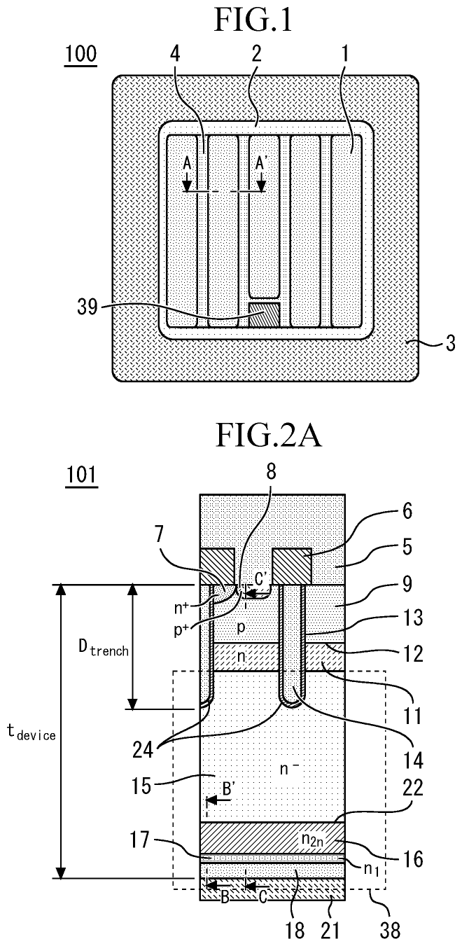

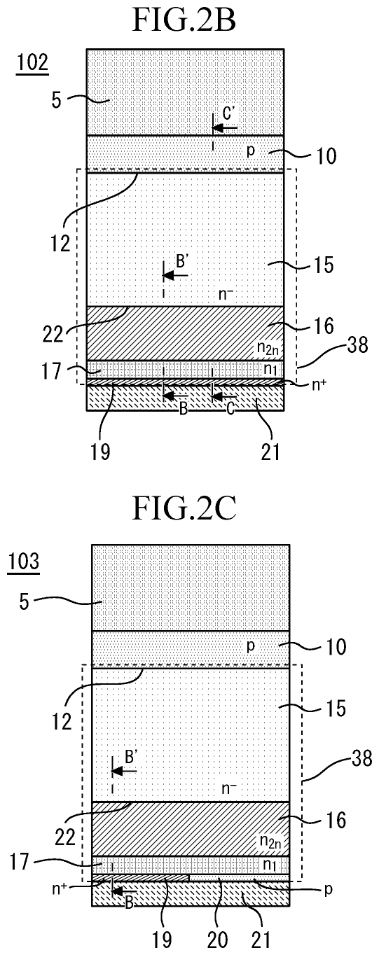

FIG. 2A is a cross-sectional view of an IGBT 101 according to the first embodiment. FIG. 2B is a cross-sectional view of a diode 102 according to the first embodiment. FIG. 2C is a cross-sectional view illustrating another example of a diode 103 according to the first embodiment. The semiconductor device 100 is, for example, the IGBT or diodes illustrated in FIGS. 2A to 2C. FIGS. 2A to C are each a cross-sectional view obtained by cutting FIG. 1 along line A-A′. The diode 102 has a p-i-n diode structure. The diode 103 has a relaxed-field-of-cathode (RFC) diode structure. Each diode according to the present embodiment may be a power diode or a freewheeling diode (FWD).

The semiconductor device 100 includes a silicon substrate having a first surface and a second surface opposite the first surface, a first electrode 5 provided on the first surface, and a second electrode 21 provided on the second surface. The silicon substrate includes an i type drift layer 15 having impurity concentration that is higher on the second surface side. An n type buffer layer 16 containing protons as impurity is provided on the second surface side of the drift layer 15. A buffer layer 17 is provided on the second surface side of the buffer layer 16. Among the buffer layers 16 and 17 of two kinds, only the buffer layer 16 contacts the drift layer 15. In the following description, the first surface side is also referred to as a front side, and the second surface side is also referred to as a back side.

The drift layer 15 contains phosphorus or antimony as a dopant. The drift layer 15 is formed by using a silicon wafer having impurity concentration Cₙ₋ of 1.0×10¹² to 5.0×10¹⁴ atoms/cm³ and manufactured by an MCZ method. A definitive device thickness t_{device} is 40 to 700 μm. Phosphorus or antimony is used as an n type dopant at MCZ wafer manufacturing. Accordingly, it is possible to reduce variation of the impurity concentration Cₙ₋ of a Si single crystal ingot in a crystal axial direction, which is attributable to a dopant segregation phenomenon due to diameter increase. In particular, the evaporation speed of antimony is about three orders of magnitude larger than that of phosphorus. The evaporation speed of P is 1.6×10⁻⁴ cm/see, and the evaporation speed of Sb is 1.3×10⁻¹ cm/sec. By producing Si single crystal with an evaporation control technology exploiting this characteristic, it is possible to significantly reduce variation of the impurity concentration Cₙ₋ of a Si single crystal ingot in a crystal axial direction.

In the diodes 102 and 103, the drift layer 15 is an area from a main junction 12 on the front side to a junction part 22 on the back side. In the IGBT 101, the drift layer 15 and a semiconductor layer 11 are provided between the main junction 12 and the junction part 22. The main junction 12 is a junction part at which the electric field intensity is highest when a depleted layer extends toward the back side for voltage holding at reverse bias application in a power semiconductor. The junction part 22 is a junction part that the depleted layer extending from the main junction 12 toward the back side at voltage holding contacts first and at which the electric field intensity is second highest at voltage holding.

In the IGBT 101 and the diodes 102 and 103, the buffer layers 16 and 17 are provided. With the buffer layer 16, it is possible to achieve loss reduction in an “off” state and improvement of controllability and the breakdown resistance amount in dynamic operation. With the buffer layer 17, it is possible to achieve stable voltage holding in the “off” state.

In the IGBT 101 illustrated in FIG. 2A, the n type semiconductor layer 11 is provided on the first surface side of the drift layer 15. The semiconductor layer 11 is formed deeper than a base layer 9 on the first surface side of the drift layer 15. The semiconductor layer 11 provides an effect of increasing carrier concentration on the first surface side in an “on” state of the IGBT. Accordingly, “ON” voltage of the IGBT can be lowered. The p type base layer 9 is provided on the first surface side of the n type semiconductor layer 11. An n⁺ type emitter layer 7 and a p⁺ type semiconductor layer 8 are provided on the first surface side of the base layer 9.

Trenches 24 are formed on the first surface of the silicon substrate. The trenches 24 penetrate through the emitter layer 7 and the base layer 9. A gate electrode 14 is provided inside each trench 24. The first electrode 5 is provided on the gate electrode 14 with an interlayer film 6 interposed therebetween. In the IGBT 101, the first electrode 5 is an emitter electrode. A p type collector layer 18 is provided on the second surface side of the buffer layer 17. The second electrode 21 is provided in contact with the collector layer 18. In the IGBT 101, the second electrode is a collector electrode.

Part of trenches 24 at a MOS transistor part are equipotential to the first electrode 5 at emitter potential. The first electrode 5 is, for example, an aluminum wire. With this structure, it is possible to achieve reduction of the saturated current density of the IGBT, reduction of oscillation in a no-load short-circuit state by control of capacitance characteristics, improvement of the short-circuit resistance amount, and low “ON” voltage due to carrier concentration increase on the emitter side.

In the diode 102 illustrated in FIG. 2B, a p type anode layer 10 is provided on the first surface side of the drift layer 15. The first electrode 5 is provided on the anode layer 10. In the diode 102, the first electrode 5 is an anode electrode. An n⁺ type cathode layer 19 is provided on the second surface side of the buffer layer 17. The cathode layer 19 contacts the second electrode 21. In the diode 102, the second electrode 21 is a cathode electrode.

The diode 103 illustrated in FIG. 2C additionally includes a p type cathode layer 20, which is different from the diode 102. The cathode layer 20 is provided on the second surface side of the buffer layer 17 and arranged alongside the cathode layer 19 in a direction along the second surface. A plurality of cathode layers 19 and 20 are alternately provided alongside in the direction along the second surface.

Examples of parameters of the diffusion layers and trenches of the IGBT 101 will be described below. Hereinafter, impurity concentration means the concentration of an element different from Si. An element that forms a diffusion layer is referred to as a dopant.

### -p Type Base Layer 9

dopant: boron, peak impurity concentration: 1.0×10¹⁶ to 1.0×10¹⁸ atoms/cm³, depth: deeper than the emitter layer 7 and shallower than the semiconductor layer 11

### -n Type Semiconductor Layer 11

dopant: arsenic or phosphorus, peak impurity concentration: 1.0×10¹⁵ to 1.0×10¹⁷ atoms/cm³, depth: deeper than the base layer 9 by 0.5 to 1.0 μm
   -n⁺ Type Emitter Layer 7
dopant: arsenic, phosphorus, peak impurity concentration: 1.0×10¹⁸ to 1.0×10²¹ atoms/cm³, depth: 0.2 to 1.0 μm
   -p⁺ Type Semiconductor Layer 8
dopant: boron, surface impurity concentration: 1.0×10¹⁸ to 1.0×10²¹ atoms/cm⁻³, depth: same as or deeper than the emitter layer 7

### -n Type Buffer Layer 16

dopant: proton, peak impurity concentration C_{P, n2n}≤0.01×C_{P, n1}, depth X_{j, nb2}: X_{j, n1}+20 to 30 μm

### -n Type Buffer Layer 17

dopant: arsenic or phosphorus, peak impurity concentration C_{P, n1}: 1.0×10¹⁵ to 5.0×10¹⁶ atoms/cm³, depth X_{j, n1}: 1.0 to 30 μm

### -p Type Collector Layer 18

dopant: boron, peak impurity concentration: 1.0×10¹⁶ to 1.0×10²⁰ atoms/cm³, depth: 0.3 to 0.8 μm
   -Trench Depth D_{trench}: 2.0 μm to Depth Deeper than n Type Semiconductor Layer 11

Examples of parameters of the diffusion layers of the diode 102 will be described below.

### -p Type Anode Layer 10

dopant: boron, surface impurity concentration: 1.0×10¹⁶ atoms/cm³ or higher, peak impurity: 2.0×10¹⁶ to 1.0×10¹⁸ atoms/cm³, depth: 2.0 to 10.0 μm

### -n Type Buffer Layer 16

dopant: proton, peak impurity concentration C_{P, n2n}≤0.01×C_{P, n1}, depth X_{j, nb2}: X_{j, n1}+20 to 30 μm

### -n Type Buffer Layer 17

dopant: arsenic or phosphorus, peak impurity concentration C_{P, n1}: 1.0×10¹⁵ to 5.0×10¹⁶ atoms/cm³, depth X_{j, n1}: 1.0 to 30 μm
   -n⁺ Type Cathode Layer 19
dopant: arsenic, phosphorus, peak impurity concentration: 1.0×10¹⁷ to 1.0×10¹⁹ atoms/cm³, depth: 0.3 to 0.5 μm

Examples of parameters of the diffusion layers of the diode 103 will be described below.

### -p Type Anode Layer 10

dopant: boron, surface impurity concentration: 1.0×10¹⁶ atoms/cm³ or higher, peak impurity: 2.0×10¹⁶ to 1.0×10¹⁸ atoms/cm³, depth: 2.0 to 10.0 μm

### -n Type Buffer Layer 16

dopant: proton, peak impurity concentration C_{P, n2n}≤0.01×C_{P, n1}, depth X_{j, nb2}: X_{j, n1}+20 to 30 μm

### -n Type Buffer Layer 17

dopant: arsenic or phosphorus, peak impurity concentration C_{P, n1}: 1.0×10¹⁵ to 5.0×10¹⁶ atoms/cm³, depth X_{j, n1}: 1.0 to 30 μm
   -n⁺ Type Cathode Layer 19
dopant: arsenic, phosphorus, peak impurity concentration: 1.0×10¹⁷ to 1.0×10¹⁹ atoms/cm³, depth: 0.3 to 0.5 μm

### -p Type Cathode Layer 20

dopant: boron, peak impurity concentration: 1.0×10¹⁶ to 1.0×10¹⁸ atoms/cm³, depth: 0.3 to 0.5 μm

In the following description, the drift layer 15, the buffer layers 16 and 17, and the collector layer 18 in the IGBT 101 are also referred to as a vertical structure 38. Similarly, the drift layer 15, the buffer layers 16 and 17, and the cathode layer 19 in the diode 102, and the drift layer 15, the buffer layers 16 and 17, and the cathode layer 19, 20 in the diode 103 are also referred to as the vertical structure 38.

Impurities such as oxygen and nitrogen are introduced into an MCZ wafer at Si wafer manufacturing. A thermal donor phenomenon attributable to oxygen atoms among these impurities occurs at a particular annealing temperature. The thermal donor phenomenon is a phenomenon that oxygen atoms in the MCZ wafer become donors in a particular temperature zone. In the present embodiment, the thermal donor phenomenon is utilized to control the impurity concentration of the drift layer 15 to a characteristic impurity profile that the impurity concentration increases from the main junction 12 toward the junction part 22. Accordingly, it is possible to reduce adverse influence on off-state voltage holding performance, in other words, static voltage resistance characteristics and improve controllability and the breakdown resistance amount in dynamic operation.

Oxygen and nitrogen introduced at MCZ wafer manufacturing exist at an interstitial position and a substitutional position, respectively, in Si single crystal. Oxygen concentration Oᵢ in an MCZ wafer is two to three orders of magnitude higher than in an FZ wafer. Nitrogen concentration Cₛ in an MCZ wafer is equivalent to that in an FZ wafer. In the present embodiment, protons are implanted from the back side and diffused from the back side to the front side to utilize the thermal donor phenomenon attributable to oxygen. Accordingly, it is possible to form a characteristic impurity profile that the impurity concentration of the drift layer 15 increases from the main junction 12 toward the junction part 22.

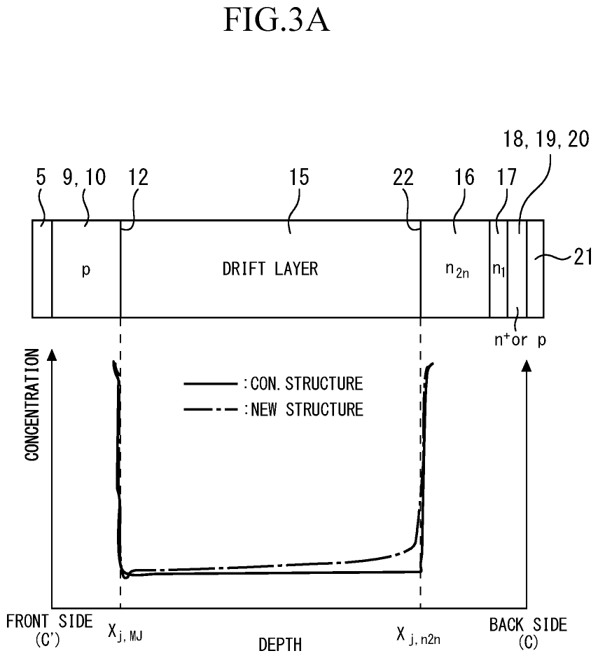

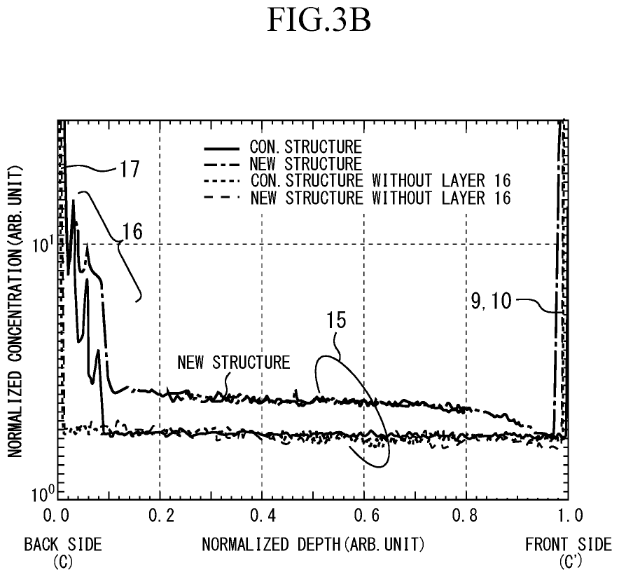

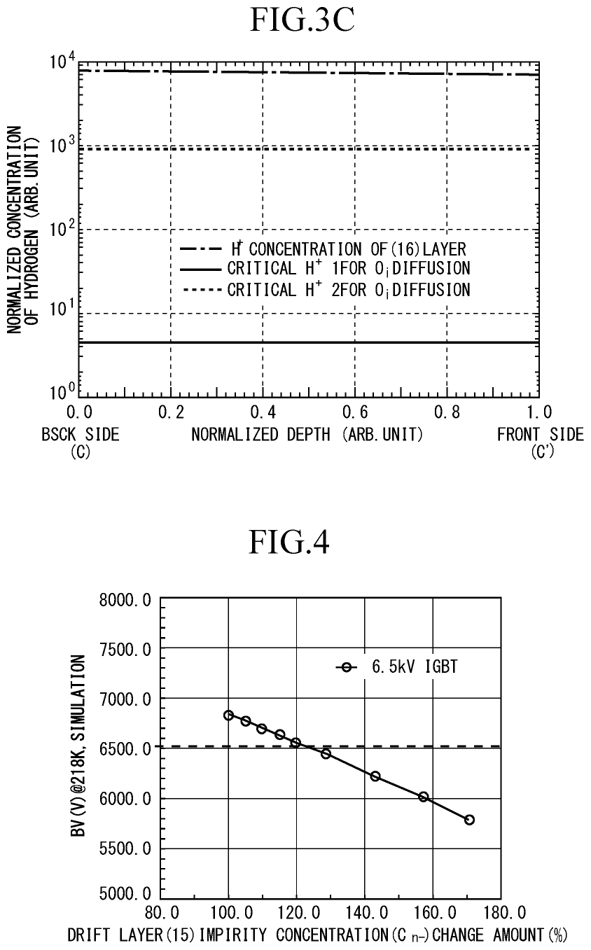

FIGS. 3A to 3C each illustrate an impurity profile along line C-C′ in FIG. 2. FIG. 3A is a diagram illustrating the impurity profile of the drift layer 15 according to the first embodiment. In FIG. 3A, “new structure” indicates the impurity profile of the present embodiment, and “con. structure” indicates the impurity profile of a comparative example. The comparative example is different from the present embodiment in that an FZ wafer is used. The impurity concentration of the drift layer 15 according to the present embodiment increases at a small gradient from X_{j, MJ} of the main junction 12 toward X_{j, n2n} of the junction part 22 as compared to that of the comparative example. The impurity concentration of the drift layer 15 may continuously increase from a part at which the drift layer 15 is joined to a layer provided on the first surface side of the drift layer 15 to a part at which the drift layer 15 is joined to the buffer layer 16.

FIG. 3B is a diagram for description of influence of the buffer layer 16 on the impurity profile of the drift layer 15. FIG. 3B illustrates the impurity profiles of “new structure” and “con. structure” with and without the buffer layer 16. The buffer layer 17 is provided in each sample illustrated in FIG. 3B. In FIGS. 3A and 3B, the horizontal axis is normalized with t_{device} illustrated in FIG. 2. As understood from FIG. 3B, a profile that the impurity concentration increases as a position is closer to the second surface side is obtained only with combination of “new structure” using an MCZ wafer and the buffer layer 16.

FIG. 3C is a calculation result of the impurity profile of hydrogen concentration in the depth direction. The buffer layer 16 is formed by implanting protons from the back side. Each of “critical H⁺1” and “critical H⁺2” is critical H⁺ concentration in a case in which oxygen diffuses in one or two. The hydrogen concentration is one to three orders of magnitude higher than the critical H⁺ concentration for oxygen to diffuse.

Protons have an effect of increasing the speed of oxygen diffusion. Thus, the thermal donor phenomenon attributable to oxygen is promoted when H⁺ exists. Hydrogen introduced from the back side diffuses to the front side by annealing at formation of the buffer layer 16 to be described later. Accordingly, thermal donor generation is more likely to be promoted on the back side than on the front side. Thus, with combination of oxygen in the drift layer 15 and protons in the buffer layer 16, it is possible to form a hydrogen impurity profile that concentration gradually decreases toward the front side.

FIG. 4 is a diagram illustrating the relation between the change amount of the impurity concentration of the drift layer 15 and voltage resistance. FIG. 4 illustrates a result of a simulation performed for a 6.5 kV IGBT. The horizontal axis represents the change amount of the impurity concentration relative to the impurity concentration of “con. structure”. The percentage 100% indicates the impurity concentration of the drift layer 15 of “con. structure” in FIG. 3A. The vertical axis represents static voltage resistance (BV) at 218 K. When the change amount becomes larger than by 20%, in other words, 120% on the horizontal axis, the voltage resistance at 218 K becomes lower than rated voltage 6500 V. Thus, the change amount of the impurity concentration of the drift layer 15 is preferably equal to or smaller than 20% relative to the impurity concentration of the drift layer 15 of “con. structure”. In other words, the change amount of the impurity concentration of the drift layer 15 is preferably equal to or smaller than 20%.

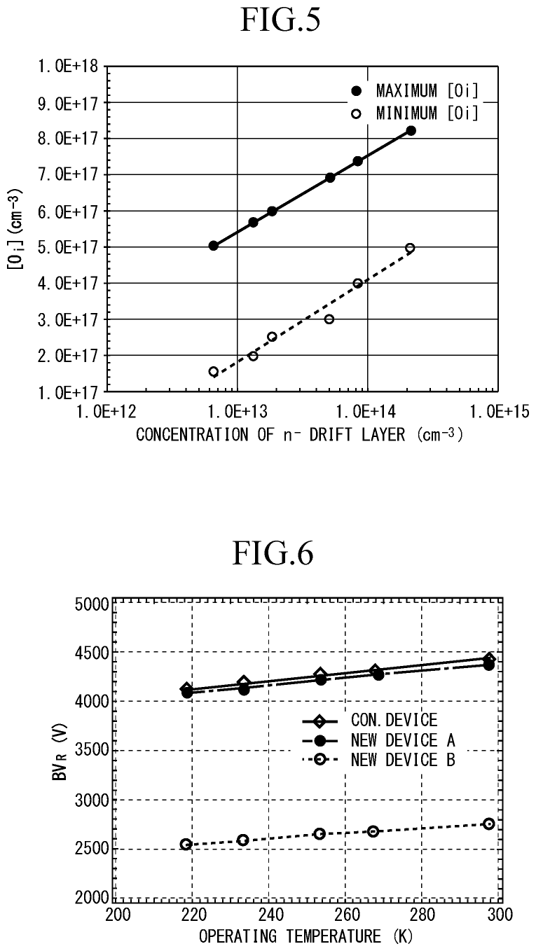

FIG. 5 is a diagram illustrating the relation between the oxygen concentration Oᵢ and the impurity concentration Cₙ₋ of the drift layer 15 in an MCZ wafer. The impurity concentration Cₙ₋ increases as a donor layer is formed by the thermal donor phenomenon in the MCZ wafer. In FIG. 5, “minimum [Oᵢ]” and “maximum [Oᵢ]” are expressed by relational expressions of Expressions (1) and (2), respectively.

$$\\ \begin{matrix}[ Math . 1 ] & \\ minimum [ {O}_{i} ] = 1. \times {10}^{17} ln ( {C}_{{n}^{{}_{} -}} ) - 2.84 \times {10}^{18} & ( 1 )\end{matrix}$$

$$\\ \begin{matrix}[ Math . 2 ] & \\ maximum [ {O}_{i} ] = 9.4 \times {10}^{16} ln ( {C}_{{n}^{{}_{} -}} ) - 2.27 \times {10}^{18} & ( 2 )\end{matrix}$$

In the expressions, “minimum [Oᵢ]” is a minimum [Oᵢ] value for achieving the impurity profile of the drift layer 15 according to the present embodiment by utilizing the thermal donor phenomenon attributable to oxygen in the MCZ wafer. In addition, “maximum [Oᵢ]” is a threshold value of [Oᵢ] for maintaining off-state voltage holding performance that is basic performance of a power semiconductor when Cₙ₋ changes through the thermal donor phenomenon attributable to oxygen in the MCZ wafer.

It is possible to reduce adverse influence on off-state voltage holding performance that is basic performance of a power semiconductor, in other words, static voltage resistance characteristics by controlling the oxygen concentration Oᵢ between “maximum [Oᵢ]” and “minimum [Oᵢ]” when Cₙ₋ changes. Thus, the oxygen concentration Oᵢ and the impurity concentration Cₙ₋ of the drift layer 15 desirably satisfy “minimum [Oᵢ]”≤Oᵢ≤“maximum [Oᵢ]”.

FIG. 6 is a diagram illustrating measured temperature dependency of static voltage resistance BV_{R} for a 3.3 kV diode. In FIG. 6, “new device A” is a device in which oxygen concentration is controlled between “maximum [Oᵢ]” and “minimum [Oᵢ]” in FIG. 4. In addition, “new device B” is a device in which concentration [Oᵢ] is higher than “maximum [Oᵢ]”. The impurity profile of the drift layer 15 in each of “new device A” and “new device B” is the characteristic impurity profile illustrated in FIG. 3A. However, “new device B” is a diode in which increase of the impurity concentration Cₙ₋ through the thermal donor phenomenon due to oxygen is larger than in “new device A”.

As a result, “new device A” has voltage resistance holding performance equivalent to that of “con. device”, but “new device B” cannot hold rated voltage 3300 V of a 3.3 kV class at 298 K and has lower off-state voltage holding performance.

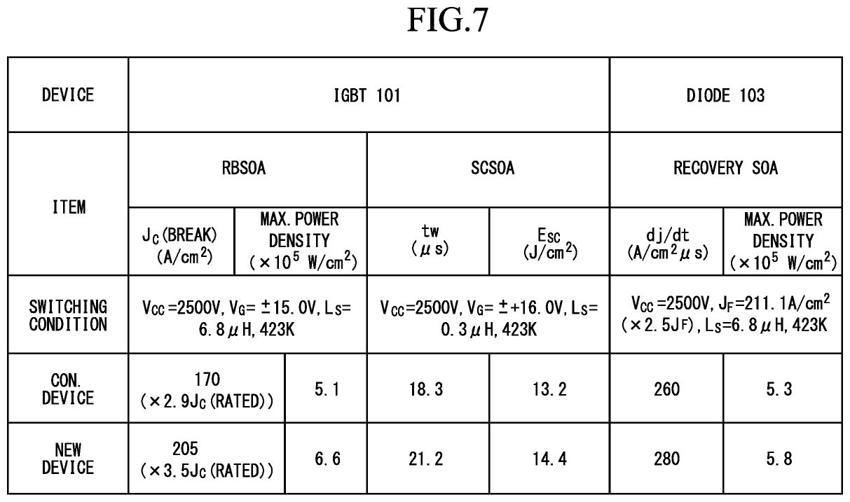

FIG. 7 is a diagram illustrating test results of a safe operating area (SOA) in a dynamic state for the 3.3 kV IGBT and diode. The impurity profiles of the drift layer 15 of “con. device” and “new device” in FIG. 7 are the same as the impurity profiles of “con. structure” and “new structure”, respectively, in FIG. 3A. In “new device”, an MCZ wafer for which [Oᵢ] is controlled between “maximum [Oᵢ]” and “minimum [Oᵢ]” is used. In “con. device”, an FZ wafer is used.

In FIG. 7, “J_{c} (break)” is the maximum cutoff current density of the IGBT at L-load switching, “Max. power density” is the maximum cutoff power density of the IGBT in turn-off operation at L-load switching or the maximum cutoff power density of the diode in recovery operation, “t_{w}” is the maximum cutoff gate pulse width of the IGBT in a no-load short-circuit state, “E_{sc}” is the maximum cutoff short-circuit energy of the IGBT in a no-load short-circuit state, and “dj/dt” is the gradient of the J_{A} waveform of the diode in recovery operation and is the maximum gradient of cutoff.

For any of the IGBT and the diode, SOA of “new device” having a characteristic impurity profile of the drift layer 15 according to the present embodiment increases as compared to that of “con. device”. This is a result of control of mutual interaction between a carrier plasma layer and electric field intensity inside the device in a dynamic state. The carrier plasma layer is a layer formed through conductivity modulation as electrons and holes are implanted into the drift layer 15 when the device is on. The carrier plasma layer is a neutral layer in which n≈p holds where n represents electron concentration and p represents hole concentration. Control of the carrier plasma layer is important for improvement of performance of an IGBT and a diode as power semiconductors.

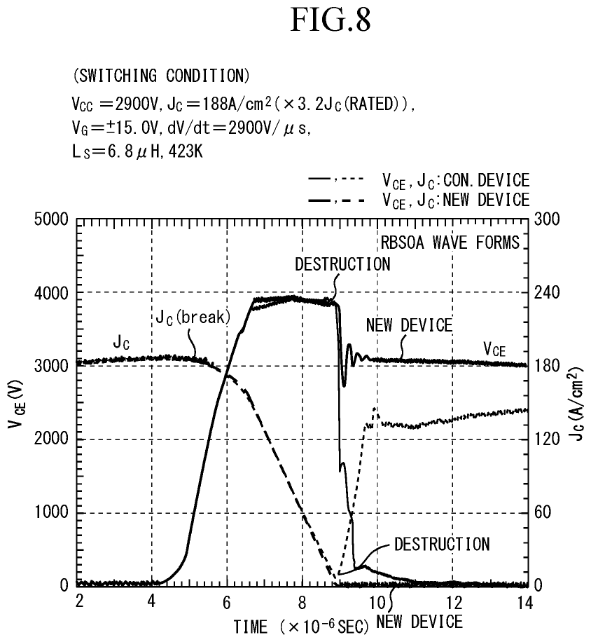

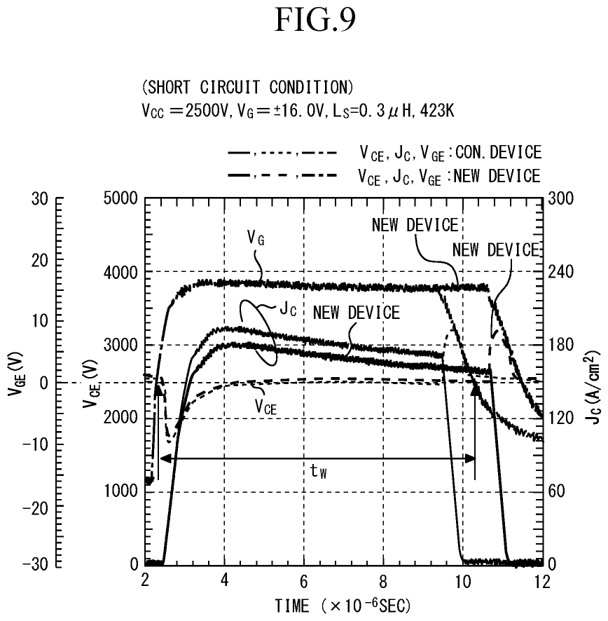

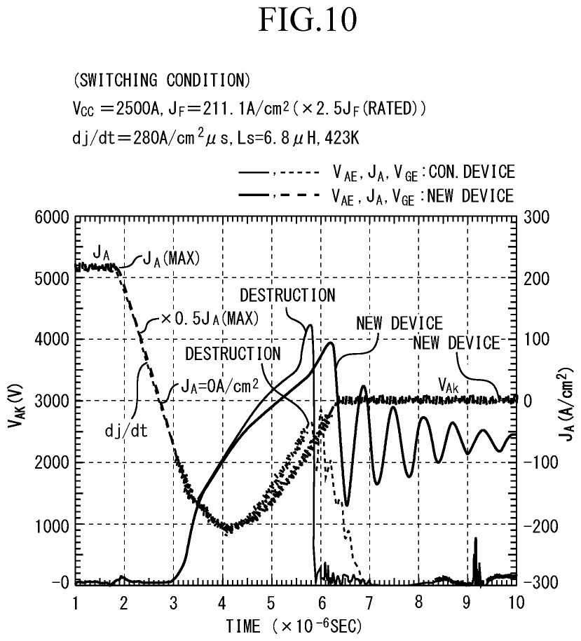

FIG. 8 is a diagram illustrating waveforms of reverse-bias (RB) SOA. FIG. 9 is a diagram illustrating waveforms of short circuit (SC) SOA. FIG. 10 is a diagram illustrating waveforms of recovery SOA. In FIGS. 8 and 10, it is understood that “new device” can be cut off under a condition under which breakdown occurs to “con. device”, and thus the breakdown resistance amount is large. FIG. 9 illustrates the waveforms in the maximum cutoff state in a short-circuit mode. It is understood that “new device” can cut off a condition with a longer pulse width than “con. device” and the breakdown resistance amount is large in the short-circuit mode.

In this manner, according to the present embodiment, it is possible to improve controllability and the breakdown resistance amount in dynamic operation without adverse influence on off-state voltage holding performance. Moreover, in the present embodiment, it is possible to form the impurity profile of the drift layer 15 having impurity concentration that is higher on the second surface side by combining the silicon substrate containing oxygen as impurity and manufactured by the MCZ method and the buffer layer 16 containing protons as impurity. Thus, it is possible to form the impurity profile of the drift layer 15 while protons do not pass through a MOS transistor area upon proton irradiation. Accordingly, it is possible to reduce degradation of MOS transistor characteristics and gate oxide film characteristics.

Concentration [Cs] of carbon, which is another impurity element introduced in an MCZ wafer during manufacturing is in the order of 1.0×10¹⁴ to 5.0×10¹⁵ atoms/cm⁻³.

In an example described in the present embodiment, the semiconductor device 100 is an IGBT or a diode, but the semiconductor device 100 may be a reverse-conducting (RC) IGBT. Specifically, the silicon substrate in the semiconductor device 100 may have an IGBT area and a diode area. The IGBT area may employ the structure of the IGBT 101. The diode area may employ the structure of any of the diodes 102 and 103.

These modifications can be appropriately applied to semiconductor devices and methods of manufacturing the semiconductor devices according to embodiments below. Meanwhile, for the semiconductor devices and the methods of manufacturing the semiconductor devices according to the embodiments below, dissimilarities with the first embodiment will mainly be explained as they have many similarities with the first embodiment.

### Second Embodiment

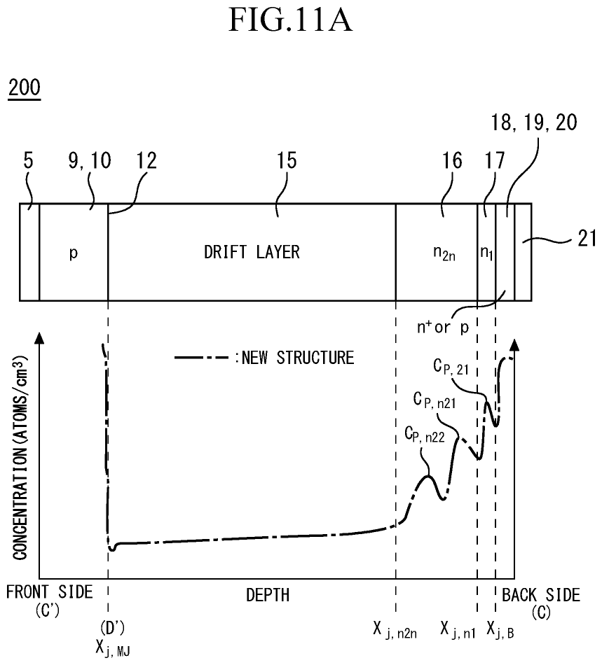

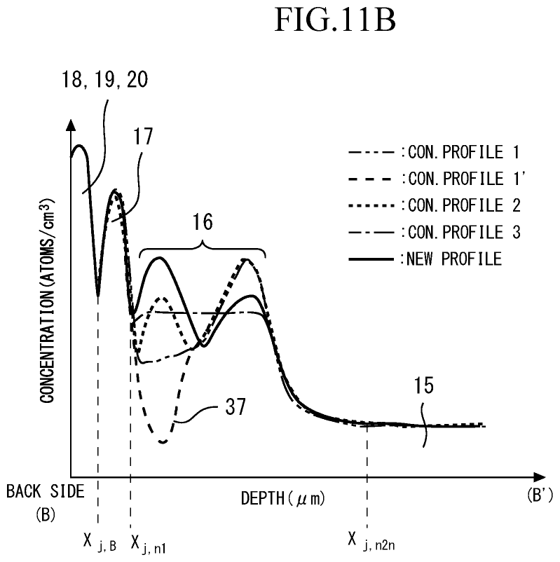

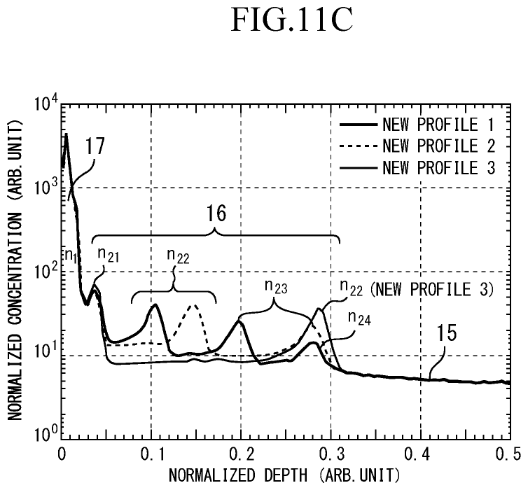

FIG. 11A is a diagram illustrating an impurity profile according to a second embodiment. FIG. 11A illustrates the impurity profile along line C-C′ in FIG. 2. In the present embodiment, the impurity profile of the buffer layer 16 is different from that in the first embodiment. The other configuration is the same as in the first embodiment. The impurity concentration of the buffer layer 16 has a plurality of peaks in the thickness direction of the silicon substrate. The impurity concentration at the plurality of peaks increases as a position is closer to the buffer layer 17.

In other words, the buffer layer 16 includes a plurality of n type layers n₂ₙ. Peak concentrations C_{P, n2n} of the plurality of layers n₂ₙ decrease from a part X_{j, n1} at which the buffer layer 16 is joined to the buffer layer 17 toward a part X_{j, n2n} direction at which the buffer layer 16 is joined to the drift layer 15. In the example illustrated in FIG. 11A, the buffer layer 16 has peaks of n=2. When C_{p, 21} represents peak concentration of the buffer layer 17 and C_{p, n21} and C_{p, n22} represent first and second peak concentrations of the buffer layer 16 closest to the buffer layer 17, C_{p, n22}<C_{p, n21}<C_{p, 21} holds.

FIG. 11B is a diagram illustrating various impurity profiles of the buffer layer 16. FIG. 11B illustrates the impurity profiles along line B-B′ in FIG. 2. In FIG. 11B, “new profile” indicates the impurity profile of the present embodiment and C_{p, n22}<C_{p, n21}<C_{p, 21} holds. In “con. profile 1”, the impurity concentration of the buffer layer 16 has only one peak. In “con. profile 2”, the impurity concentration of the buffer layer 16 at peaks is lower at a position closer to the buffer layer 17. The profile “con. profile 3” is an impurity concentration profile in which the impurity concentration of the buffer layer 16 has no peak and is substantially constant.

In “con. profile 1′”, an area 37 having concentration lower than the impurity concentration of the drift layer 15 exists in the buffer layer 16. The buffer layer 16 is formed as H⁺ introduced to form the buffer layer 16 forms a composite defect through reaction with a point defect in Si and becomes a donor layer. The area 37 is a layer formed when H does not react with a point defect in Si because H⁺ does not diffuse toward the back side and there is no H⁺ necessary for reaction between H⁺ and a point defect in Si.

The behavior that H⁺ does not diffuse toward the back side depends on the oxygen concentration Oᵢ in the MCZ wafer. As the oxygen concentration increases, H⁺ is more likely to be trapped in a composite defect attributable to oxygen in Si and prevented from diffusing. The composite defect is, for example, vacancy-oxygen pair (VO), interstitial carbon-interstitial oxygen pair (CᵢOᵢ), or di-vacancy (V₂). When trapped in these composite defects, H⁺ become VOH, CᵢOᵢHₙ, and V₂H₂.

However, with “new profile” corresponding to the present embodiment, the impurity concentration of the buffer layer 16 has a plurality of peaks. This structure is obtained by introducing H⁺ into Si from the back side with an ion implantation technology using a plurality of acceleration energies as described later. In this case, H⁺ is compensated even in a state in which H⁺ cannot diffuse toward the back side due to high oxygen concentration. Accordingly, it is possible to prevent formation of the area 37 having concentration lower than the impurity concentration of the drift layer 15 as illustrated in “new profile” in FIG. 11B.

FIG. 11C is a diagram illustrating the impurity profile of the buffer layer 16 according to a modification of the second embodiment. As illustrated in “new profile 1” and “new profile 2”, the buffer layer 16 may have three or more peaks of impurity concentration. As illustrated in “new profile 3”, the peaks of impurity concentration may be separately provided on the first and second surface sides of the buffer layer 16. In FIG. 11C, the horizontal axis is normalized with t_{device} illustrated in FIG. 2.

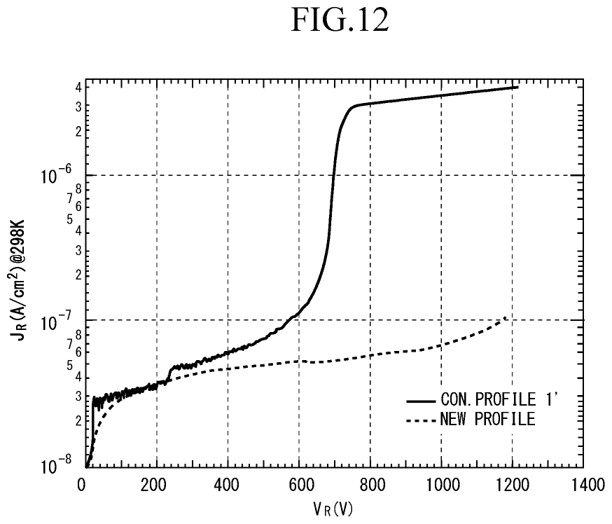

FIG. 12 is a diagram illustrating the waveform of the diode 103 at voltage resistance holding. FIG. 12 illustrates the waveform of a 1200 V diode having the structure of the diode 103 at voltage resistance holding at 298 K. The low-concentration area 37 exists in a diode of “con. profile 1′”. Thus, characteristic leakage characteristics that leakage current increases are observed when a depleted layer extending from a main junction X_{J, MJ} reaches the area 37. This causes decrease of voltage resistance holding performance and increase of loss=V_{R}×J_{R} in the “off” state. However, with “new profile” according to the present embodiment, leakage current does not abruptly increase and voltage resistance holding is possible.

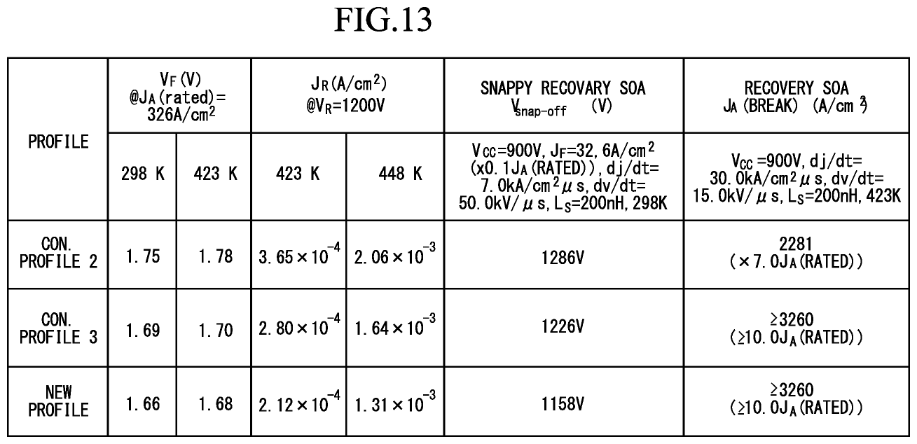

FIG. 13 is a diagram illustrating device characteristics of the diode 103. In FIG. 13, device characteristics of a 1200 V diode having the structure of the diode 103 are illustrated for “con. profile 2”, “con. profile 3”, and “new profile” illustrated in FIG. 11B. With “new profile” according to the present embodiment, it is possible to achieve low “ON” voltage V_{F} and achieve small leakage current J_{R} at 1200 V holding as compared to “con. profile 2” and “con. profile 3”. Moreover, large SOA in a dynamic state can be ensured.

In a diode having “new profile” of the buffer layer 16 according to the present embodiment, it is possible to slow down extension of a depleted layer when the depleted layer reaches the buffer layer 16 from the main junction X_{J, MJ} in dynamic operation and leave carriers on the back side. This behavior occurs due to an effect of controlling mutual interaction between a carrier plasma layer and electric field intensity in an IGBT or a diode in dynamic operation.

In SOA in a snappy mode, maximum voltage V_{snap-off} in recovery operation is lower than rated voltage 1200 V of a 1200 V device. In this manner, it is possible to suppress breakdown and improve controllability in dynamic operation and increase cutoff current density J_{A} (break) in recovery operation in SOA in a large current mode.

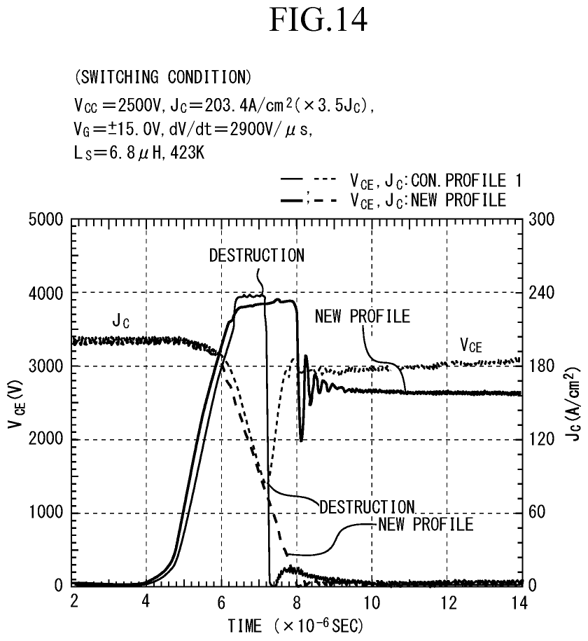

FIG. 14 is a diagram illustrating the waveform of RBSOA. In FIG. 14, cutoff performance under an L-load switching condition is illustrated for 3.3 kV IGBTs having “con. profile 1” and “new profile” illustrated in FIG. 11B. The IGBT with “new profile” according to the present embodiment shows improved cutoff performance as compared to that with “con. profile 1”. Thus, for an IGBT as well, it is possible to achieve dynamic SOA increase with “new profile” according to the present embodiment.

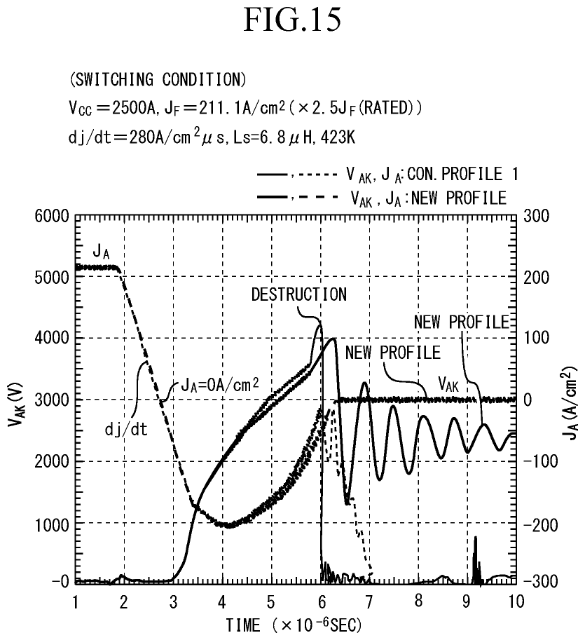

FIG. 15 is a diagram illustrating the waveform of Recovery SOA. In FIG. 15, cutoff performance under an L-load switching condition is illustrated for 3.3 kV diodes having “con. profile 1” and “new profile” illustrated in FIG. 11B. The high voltage (HV) diode with “new profile” shows improved cutoff performance as compared to that with “con. profile 1”.

The same results as illustrated in FIGS. 13 to 15 are obtained with “new profile 1” to “new profile 3” as modifications of the impurity profile of the buffer layer 16 according to the present embodiment illustrated in FIG. 11C.

With “new profile” of the buffer layer 16 according to the present embodiment only, it is possible to achieve the effect of controlling mutual interaction between carrier concentration and electric field intensity in an IGBT or a diode in dynamic operation. Thus, the buffer layer 16 according to the present embodiment having a plurality of peaks in impurity concentration may be applied to an FZ wafer.

### Third Embodiment

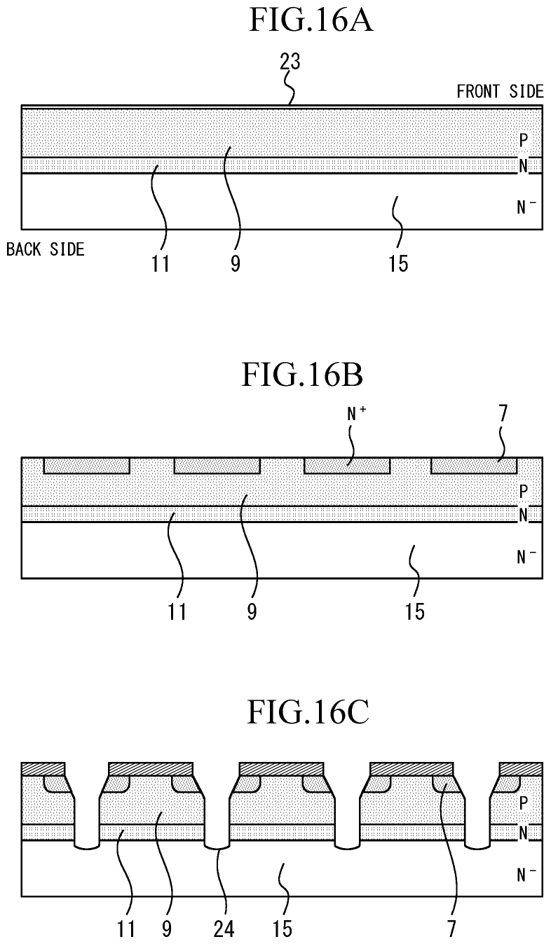

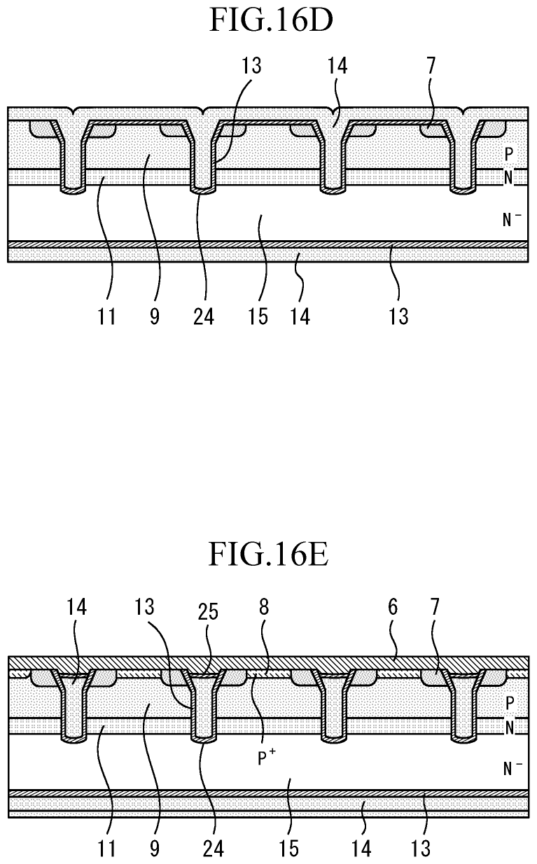

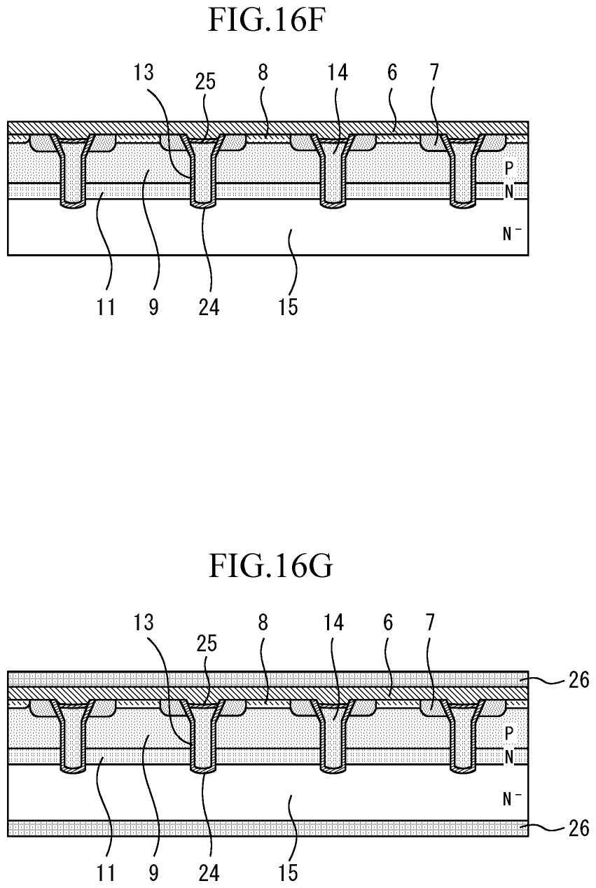

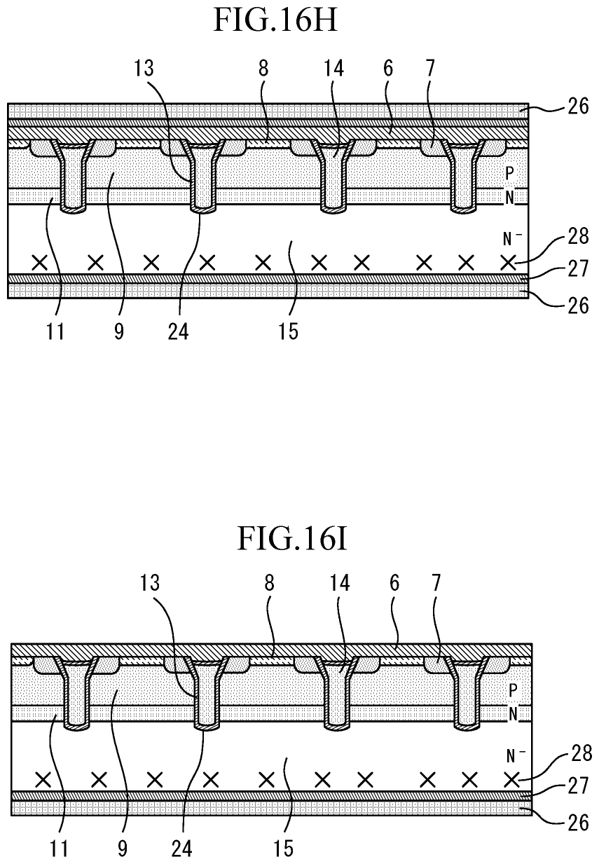

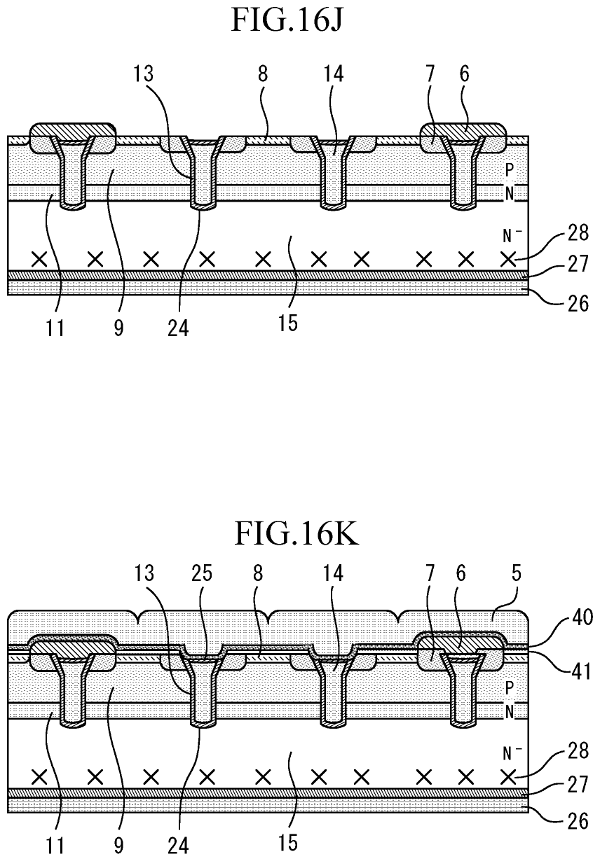

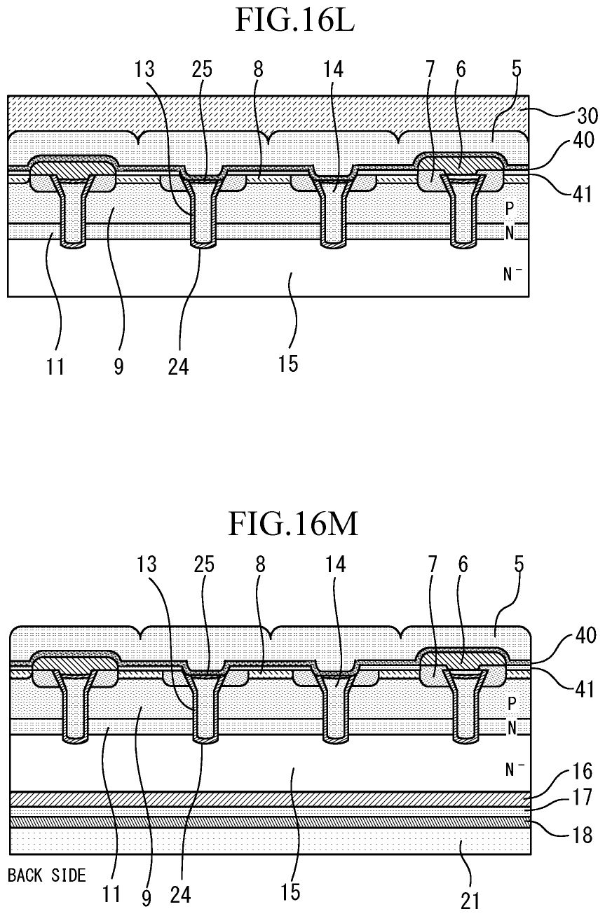

A method of manufacturing the IGBT 101 of the first and second embodiments will be described below. FIGS. 16A to 16M are diagrams for description of the method of manufacturing the IGBT 101 according to a third embodiment. FIGS. 16A to 16M are cross-sectional views at a position corresponding to line A-A′ in FIG. 1. First, a semiconductor layer is formed on the first surface of a silicon wafer manufactured by the MCZ method and including the n type drift layer 15. Specifically, as illustrated in FIG. 16A, after an oxide film 23 is formed, the base layer 9 and the semiconductor layer 11 are formed on the front side of the drift layer 15 with, for example, photolithography, etching, ion implantation, and annealing technologies. Subsequently, as illustrated in FIG. 15B, the emitter layers 7 are partially formed on the front side with ion implantation and annealing technologies.

Thereafter, as illustrated in FIG. 16C, the trenches 24 are formed with etching technologies.

In addition, cleaning, smoothing, and rounding of the inner wall of each trench are performed with etching and oxidation technologies. Subsequently, as illustrated in FIG. 16D, a gate oxide film 13 is formed on the inner wall of each trench. In addition, each trench 24 is filled with a d-poly Si film to be the gate electrode 14. The d-poly Si film is a polysilicon film doped with an n type element such as As or phosphorus at high concentration of 1×10¹⁹ atoms/cm³ or higher.

Subsequently, as illustrated in FIGS. 16E to 16H, a gettering layer constituted by a high concentration n⁺ layer 27 and a high crystal defect density layer 28 is formed on the wafer back surface to recover the carrier lifetime of the drift layer 15. The high concentration n⁺ layer 27 has surface concentration of 1.0×10²⁰ to 1.0×10²² cm⁻³ and a depth of 1.0 to 10 μm. Accordingly, the carrier lifetime of the drift layer 15 is equal to or longer than a value calculated by Expression 3 below.

$$\\ \begin{matrix}[ Math . 3 ] & \\ {τ}_{t} \geq 1.5 \times {10}^{- 5} exp ( 5.4 \times {10}^{{}_{} 3} {t}_{{n}^{{}_{} -}} ) & ( 3 )\end{matrix}$$

In the expression, t_{N-} represents the thickness (m) of the drift layer 15, and τₜ represents the carrier lifetime (sec) of the drift layer 15 with which the carrier lifetime has no influence on IGBT “ON” voltage. In Expression (3), t_{N-} is a device parameter corresponding to t_{device} in FIG. 2.

IGBT and diode “ON” voltages depend on the carrier lifetime of the drift layer 15. Expression (3) is an indicator of a carrier lifetime necessary for minimizing the dependency. When the carrier lifetime can be set to be equal to or longer than τₜ calculated by Expression (3), influence of the carrier lifetime on a switching loss can be controlled to be minimum. In addition, off-loss reduction and thermal runaway reduction can be achieved since the off-loss is affected by the carrier lifetime.

Subsequently, a method of forming the gettering layer will be described below in detail. First, as illustrated in FIG. 16E, the d-poly Si film to be the gate electrode 14, which is formed on the first surface of the wafer, is removed, an oxide film 25 is formed on the surface of the d-poly Si film, and the interlayer film 6 is formed on the first surface of the wafer. Subsequently, as illustrated in FIG. 16F, etching is selectively performed only on the wafer back surface to expose a Si surface on the wafer back surface. Accordingly, the gate oxide film 13 on the wafer back surface and the d-poly Si film are removed. The etching uses hydrofluoric acid or mixed acid liquid. The mixed acid is, for example, compound liquid of hydrofluoric acid, nitric acid, and acetic acid.

Subsequently, as illustrated in FIG. 16G, polysilicon 26 doped with an element that forms the high concentration n⁺ layer 27 is formed by an LPCVD method as a source for forming the high concentration n⁺ layer 27 and the high crystal defect density layer 28. The polysilicon 26 is d-poly Si. An element, such as phosphorus, arsenic, or antimony, which can diffuse in Si and form an n⁺ layer may be selected as the element that forms the high concentration n⁺ layer 27. The polysilicon 26 is a film doped with impurity at high concentration of 1×10¹⁹ atoms/cm³ or higher, and has a film thickness equal to or larger than 500 nm. With the polysilicon 26 doped with high concentration impurity, the high concentration impurity diffuses in the Si surface on the wafer back surface by annealing thereafter. Accordingly, high density dislocations and lattice defects including the high crystal defect density layer 28 are introduced in formation of the high concentration n⁺ layer 27.

Specifically, after deposit of the polysilicon 26, thermal annealing is performed in a nitrogen atmosphere at 900 to 1000° C. Subsequently, 900 to 1000° C. is lowered to 500 to 700° C. at an optional fall speed, and thermal annealing is performed in a nitrogen atmosphere at a temperature lower than the previous annealing temperature. Accordingly, impurity in d-poly Si diffuses into Si on the wafer back surface where the polysilicon 26 directly contacts Si. As a result, as illustrated in FIG. 16H, the high concentration n⁺ layer 27 is formed. In addition, crystal defects, in other words, the high crystal defect density layers 28 are secondarily generated in formation of the high concentration n⁺ layer 27.

Since the polysilicon 26 and the Si surface having different thermal expansion coefficients directly contact each other, distortion occurs to their interface part, in other words, a surface layer part of the high concentration n⁺ layer 27 with annealing technologies. As a result, distortion layers existing in surface layer parts of the high concentration n⁺ layer 27, the high crystal defect density layer 28, and the polysilicon 26 become gettering sites. With this configuration, heavy metal and contamination atoms taken into the wafer in a wafer process diffuse in a crystal lattice during the above-described annealing at 500 to 700° C. and move to the gettering sites. As a result, the heavy metal and contamination atoms can be captured.

With the present technology, τₜ of the drift layer 15, which has decreased in a wafer process so far, can be recovered. Thus, as indicated in Expression (3), it is possible to achieve the drift layer 15 having a sufficiently long carrier lifetime to avoid influence on electric characteristics of IGBTs in various kinds of voltage resistance classes.

The same effect is obtained by forming a high crystal defect density layer on the wafer back surface by using a laser annealing technology instead of the polysilicon 26. This laser annealing technology is a local annealing technology that involves rapid heating and rapid cooling using a laser having a wavelength of 500 to 1000 nm. In this case, the power density of laser annealing is 4 J/cm² or higher. Thereafter, the same annealing as in the method using the polysilicon 26 is performed. Specifically, thermal annealing in a nitrogen atmosphere at 900 to 1000° C. is performed, and after the temperature is lowered from 900 to 1000° C. to 500 to 700° C. at an optional fall speed, low-temperature thermal annealing is performed in a nitrogen atmosphere at 500 to 700° C. Accordingly, heavy metal and contamination atoms move to the gettering sites, and the effect of carrier lifetime improvement is obtained.

After the gettering layer is formed, as illustrated in FIG. 16I, the polysilicon 26 formed on the first surface of the wafer is removed. In addition, as illustrated in FIG. 16J, the interlayer film 6 is selectively removed to form contact holes through which the Si surface of the n⁺ type emitter layer 7 or the p⁺ type semiconductor layers 8 is exposed on the first surface of the drift layer 15 on the front side. Subsequently, as illustrated in FIG. 16K, the first electrode 5 that is an aluminum wire film is formed on the interlayer film 6 and in the contact holes by using a sputtering method technology. The first electrode 5 has a stacking structure including an aluminum metal obtained by adding Si or Cu to Al, a barrier metal 40, and a silicide layer 41 formed through reaction between exposed Si and metal. The aluminum metal is, for example, AlSi, AlSiCu, or AlCu. The barrier metal 40 is, for example, TiN or TiW. The silicide layer 41 is, for example, TiSi₂, PtSi, or CoSi. Subsequently, as illustrated in FIG. 16L, a passivation film 30 is formed on the first electrode 5. In addition, the polysilicon 26, the high concentration n⁺ layer 27, and the high crystal defect density layer 28 are removed through a polishing step and a wet etching step thereafter.

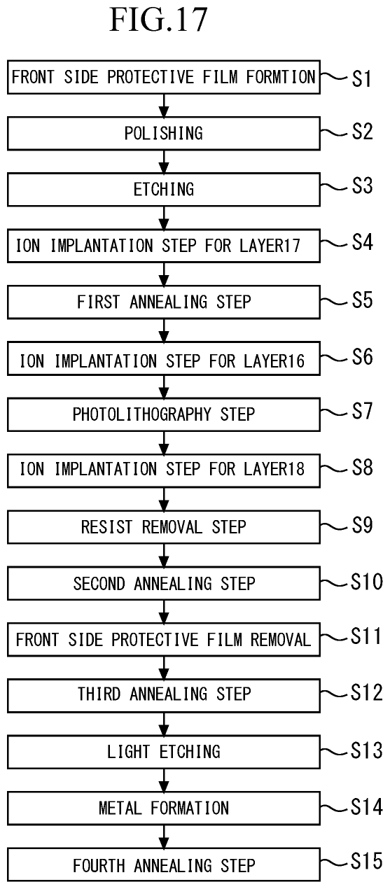

Subsequently, as illustrated in FIG. 16M, the vertical structure 38 including the buffer layers 16 and 17 is formed. FIG. 17 is a flowchart illustrating a method of forming the vertical structure 38 according to the third embodiment. The MOS transistor structure constituting an IGBT, the aluminum wire, and the passivation film 30 already exist on the first surface side on which the vertical structure 38 is not formed. Thus, at formation of the buffer layers 16 and 17 and the collector layer 18 included in the vertical structure 38, the first surface side is set to have a temperature lower than the melting point of the first electrode 5, in other words, the melting point 660° C. of aluminum. Specifically, laser annealing using a laser having a wavelength with which heat is not transferred to the first surface, or annealing in a diffusion furnace at a temperature equal to or lower than the metal melting point is selected with taken into account the temperature gradient in the device depth direction.

The buffer layers 16 and 17 are formed after a step of accurately forming the device thickness t_{device}=40 to 700 μm as illustrated in FIG. 16L. In this case, the high concentration n⁺ layer 27, the high crystal defect density layer 28, and the polysilicon 26 are removed. However, the carrier lifetime of the drift layer 15 is a value that satisfies Expression (3).

In FIG. 17, a front side protective film formation step (S1) corresponds to the above-described step of forming the passivation film 30. Polishing (S2) and etching (S3) correspond to the step illustrated in FIG. 16L.

In a process according to the present embodiment, the order of forming the buffer layers 16 and 17 and peak position setting of acceleration energy at introduction of the buffer layer 16 are important. In the present embodiment, as illustrated in FIGS. 16A to 16L, a semiconductor layer is formed on the first surface side of a silicon wafer, and then ion implantation is performed into the second surface of the silicon wafer (S4) and annealing is performed (S5) to form the buffer layer 17. After the buffer layer 17 is formed, protons are implanted at a position deeper than the buffer layer 17 with respect to the second surface (S6), and after the protons are implanted, annealing is performed for the protons (S12) to form the buffer layer 16. Hereinafter, S5 is also referred to as a first annealing step, and S12 is also referred to as a third annealing step. The annealing (S12) for the protons of the buffer layer 16 is preferably performed, for example, for 90 minutes or longer at 375 to 425° C.

Before the annealing is performed for the protons (S12) after the protons are implanted (S6), ion implantation is performed into the second surface and annealing is performed to form a p type layer shallower than the buffer layer 17. In the example illustrated in FIG. 17, the collector layer 18 is formed as the p type layer.

The annealing step for forming the buffer layer 17 is performed at a higher temperature than the annealing step for forming the buffer layer 16. Thus, in a case in which the buffer layer 17 is formed after the buffer layer 16 is formed, adverse influence potentially occurs to the impurity profile of the buffer layer 16 after activation and the kinds of lattice defects introduced to form the buffer layer 16. Accordingly, adverse influence potentially occurs to carriers in the device “on” state. Thus, the buffer layer 16 is preferably formed after the buffer layer 17 is formed.

The buffer layer 16 of the second embodiment can be formed by introducing protons into Si with two or more kinds of different acceleration energies and dose amounts and performing annealing (S12) after the activation annealing (S5) of the buffer layer 17. The buffer layers 16 and 17 are formed to satisfy the following relation. The peak position of the buffer layer 16 is set to be positioned on the X_{j, n2n} junction part side relative to the junction part X_{j, n1} of the buffer layers 16 and 17. Accordingly, the buffer layer 16 can be accurately formed without interference between the buffer layers 16 and 17.

The buffer layer 17 is formed by using As or phosphorus as a dopant. The buffer layer 16 is formed by using protons as a dopant. Ion implantation is performed a plurality of times to implant protons. The plurality of times of ion implantation are performed with conditions in descending order of acceleration energy and in a smaller dose amount as the acceleration energy increases. In other words, ion implantation is sequentially performed from the drift layer 15 side to the buffer layer 17 side with lower acceleration energy and in a larger dose amount.

The buffer layer 16 may be formed with an irradiation technology using a cyclotron instead of ion implantation.

When protons are introduced into Si, a composite defect is formed through reaction between a void v generated at the introduction and impurity such as oxygen or carbon in Si. Hydrogen contained in the composite defect becomes a donor as an electron supply source. When the donor concentration increases through composite defect density increase due to annealing, the donor concentration increases due to promotion of the thermal donor phenomenon attributable to ion implantation or an irradiation process. As a result, the buffer layer 16 that is a donor-doped n layer is formed with impurity concentration higher than that of the drift layer 15.

In the present embodiment, device performance can be improved by utilizing the composite defects formed in the buffer layer 16. However, the composite defects include a defect acting as a lifetime killer that shortens the carrier lifetime. Thus, the process of forming the buffer layer 16 by ion implantation and annealing technologies after the buffer layer 17 is formed is important for removing any defect acting as a lifetime killer by controlling the composite defects formed in the buffer layer 16 and for achieving profile stability of the buffer layer 16. Moreover, since the peak position of the buffer layer 16 is set to be positioned on the X_{j, n2n} junction part side relative to the junction part X_{j, n1} of the buffer layers 16 and 17, the buffer layer 17 and a layer n₂₁ do not interfere with the buffer layer 17. The layer n₂₁ is a layer constituting the buffer layer 16 and joining the buffer layer 17. Thus, a plurality of diffusion layers can be accurately formed.

After the proton inplantation (S6), a photolithography step (S7) and an ion implantation step (S8) for forming the collector layer 18 are performed. In addition, after resist removal step (S9), a second annealing step (S10) is performed to form the collector layer 18. The second annealing step may be the same annealing technology as the first annealing step. The second annealing step may use laser annealing or an annealing technology at a temperature equal to or lower than the metal melting point.

Subsequently, the front side protective film is removed (S11), and the above-described third annealing step for protons is performed (S12). Subsequently, light etching (S13) is performed, and a metal as the second electrode 21 is deposited by a sputtering method (S14). Subsequently, an alloy layer or a silicide layer is formed on a Si surface and a metal interface through a fourth annealing step (S15). The second electrode 21 is a metal that contacts the collector layer 18 and is, for example, an AlSi film having a Si additive amount of 1 to 3% or a multilayer film containing Ni. The fourth annealing step is performed at the temperature of 300 to 400° C., which is lower than temperature in the third annealing step.

According to the present embodiment, an MCZ wafer having high oxygen concentration is used, protons are implanted from the back side, and H⁺ is diffused from the back side to the front side by annealing. Accordingly, the thermal donor phenomenon attributable to oxygen in Si can be more promoted on the back side than on the front side, and thus a sloped impurity profile of the drift layer 15 can be formed.

### Fourth Embodiment

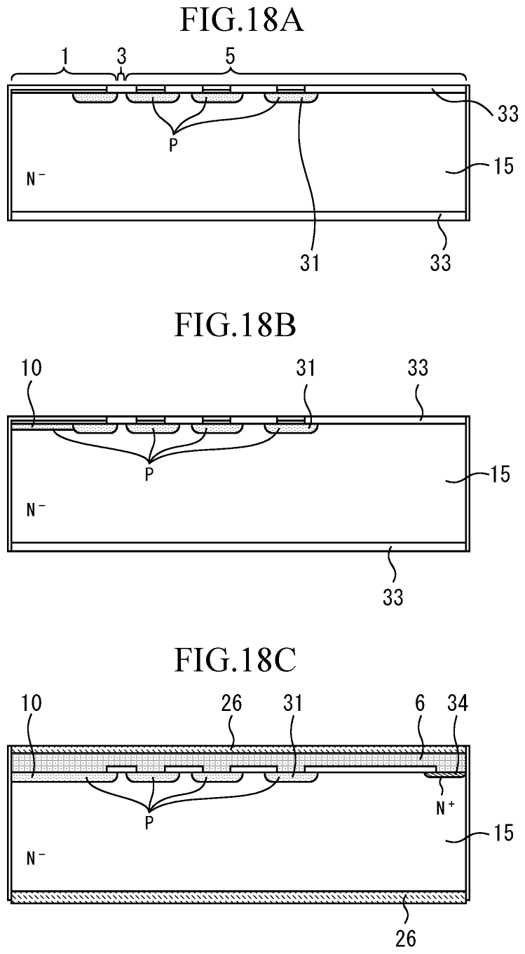

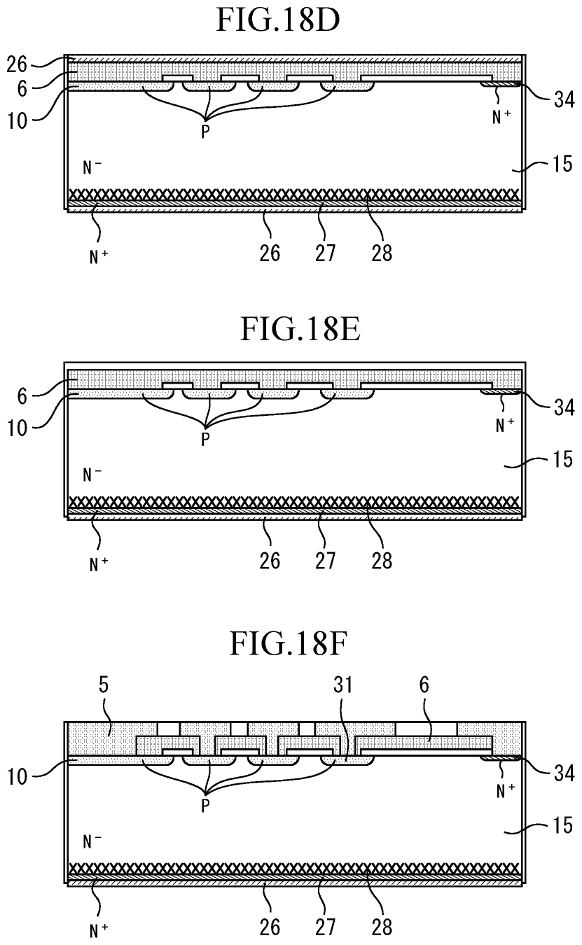

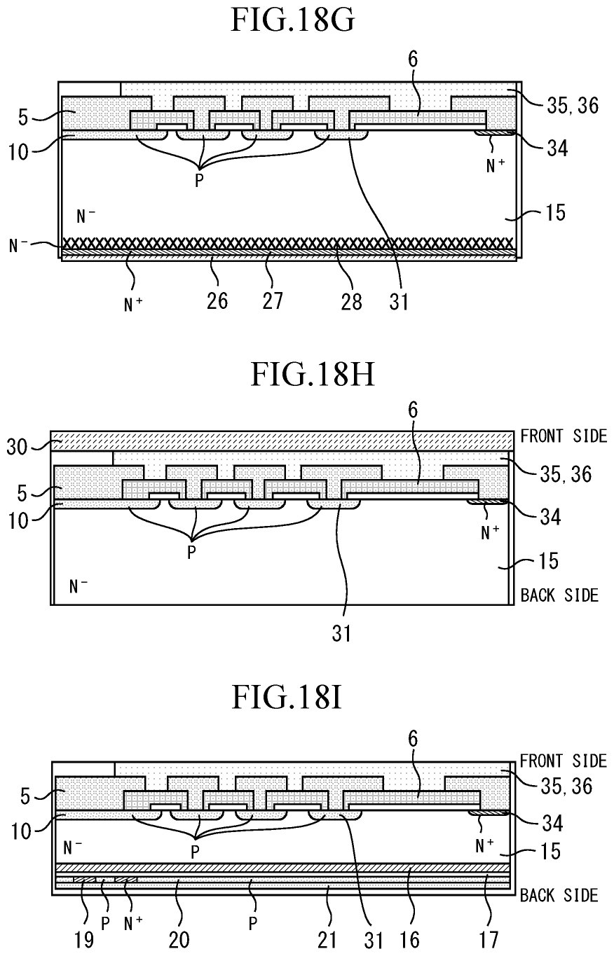

A method of manufacturing the diode 103 of the first and second embodiments will be described below. FIGS. 18A to 181 are diagrams for description of a method of manufacturing the diode 103 according to a fourth embodiment. First, as illustrated in FIGS. 18A to 18C, an oxide film 33 is formed on the front side, and photolithography is performed on the oxide film 33. Subsequently, ion implantation is performed through an opening part of the oxide film 33, and after removal of a resist used at the photolithography, annealing is performed to form a p layer 31 and an n⁺ layer 34 of the edge termination area and the anode layer 10 of an active area. Thereafter, as illustrated in FIG. 18C, the interlayer film 6 as an oxide film is formed.

Subsequently, as illustrated in FIG. 18D, gettering sites are formed from distortion layers existing in surface layer parts of the high concentration n⁺ layer 27, the high crystal defect density layer 28, and the polysilicon 26 by the same method as in the third embodiment. Accordingly, the carrier lifetime of the drift layer 15 can be set to satisfy Expression (3).

Subsequently, as illustrated in FIG. 18E, the polysilicon 26 is removed when existing on the front side. Subsequently, contact holes for contacting the p layer 31, the n⁺ layer 34, and the anode layer 10 are formed at the interlayer film 6. Thereafter, as illustrated in FIGS. 18F and 18G, the first electrode 5 and passivation films 35 and 36 are formed.

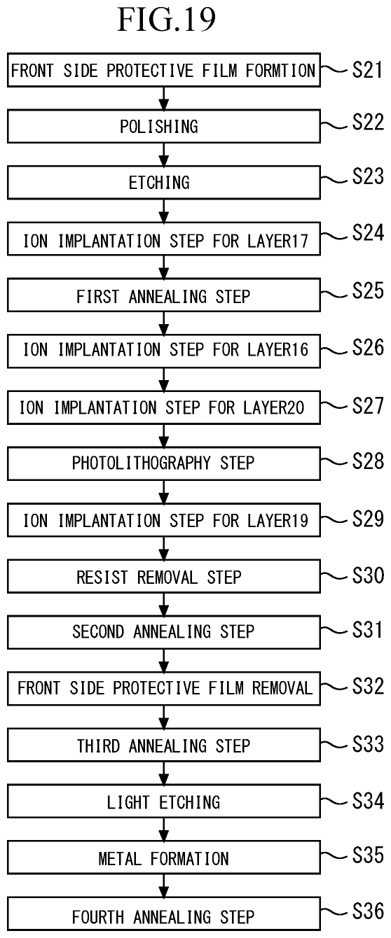

FIG. 19 is a flowchart illustrating the method of forming the vertical structure 38 according to the fourth embodiment. The method of forming the vertical structure 38 is the same as the formation method according to the third embodiment except that the cathode layers 19 and 20 are formed in place of the collector layer 18. As illustrated in FIG. 18H, the passivation film 30 is formed as the front side protective film (S21), and polishing (S22) and etching (S23) of the second surface are performed. S24 to S26 are the same as S4 to S6 in the third embodiment.

Subsequently, ion implantation for forming the cathode layer 20 is performed (S27). Subsequently, photolithography technologies are used (S28), and ion implantation (S29) for forming the cathode layer 19 is performed to partially form the cathode layer 19 on the back side. S30 to S36 are the same as S9 to S15 in the third embodiment. Accordingly, the diode 103 as illustrated in FIG. 18I can be manufactured.

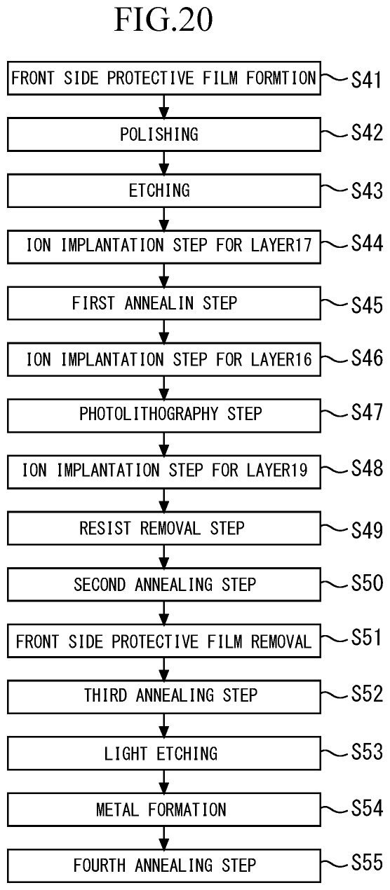

FIG. 20 is a flowchart illustrating a method of forming the vertical structure 38 according to a modification of the fourth embodiment. FIG. 20 illustrates the method of forming the vertical structure 38 in the diode 102. Since the cathode layer 20 does not exist in the diode 102, the ion implantation step for the cathode layer 20, the photolithography step for partially forming the cathode layer 19 on the back side, and the subsequent resist removal step do not exist. The other steps are the same as steps of manufacturing the diode 103. Specifically, S41 to S46 are the same as S21 to S26, and S47 to S55 are the same as S28 to S36.

### Fifth Embodiment

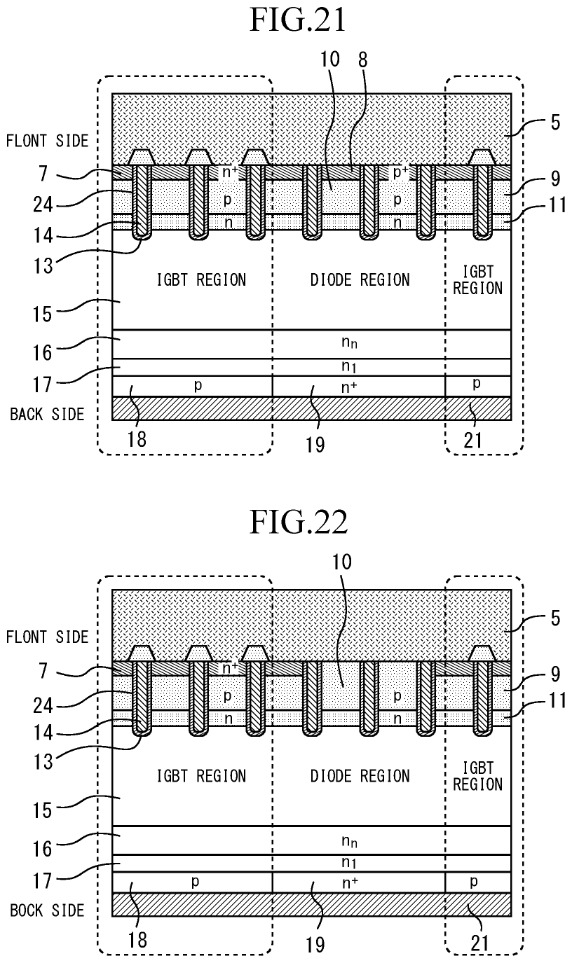

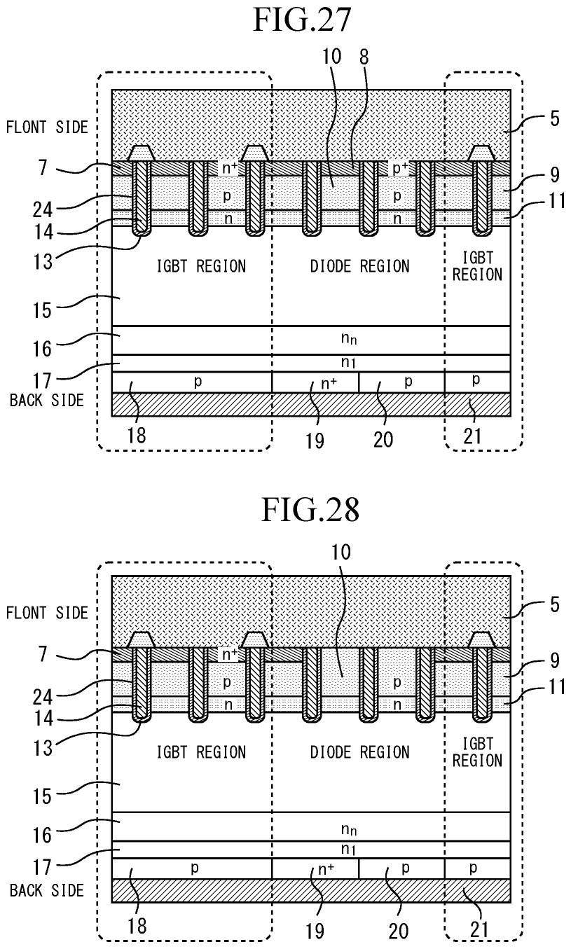

In the present embodiment, an example in which the semiconductor device 100 is an RC-IGBT will be described below. FIGS. 21 to 28 are cross-sectional views illustrating an examples of the semiconductor device 100 according to a fifth embodiment. FIGS. 21 to 28 are cross-sectional views obtained by cutting FIG. 1 along line A-A′. In the semiconductor device 100 according to the present embodiment, the silicon substrate has an IGBT area and a diode area.

The structure of the IGBT area of the semiconductor device 100 illustrated in FIG. 21 is the same as the structure of the IGBT 101 in the first embodiment. The diode area in FIG. 21 includes the n type semiconductor layer 11 provided on the first surface side of the drift layer 15, and the p type anode layer 10 provided on the first surface side of the semiconductor layer 11. The diode area also includes the p⁺ type semiconductor layer 8 that is an impurity diffusion layer provided on the first surface side of the anode layer 10 and having impurity concentration higher than that of the anode layer 10. The diode area additionally includes the n type cathode layer 19 provided on the second surface side of the buffer layer 17. The semiconductor layer 11 is formed deeper than the base layer 9 on the first surface side of the drift layer 15 in the IGBT area and formed deeper than the anode layer 10 on the first surface side of the drift layer 15 in the diode area.

The drift layer 15 illustrated in FIGS. 21 to 28 has the same characteristic impurity profile as the first embodiment. The impurity concentration Cₙ₋ of the drift layer 15 is 1.0×10¹² to 5.0×10¹⁴ atoms/cm³, and the definitive t_{device} is 40 to 700 μm.

Examples of parameters of diffusion layers and trenches included in the RC-IGBT illustrated in FIG. 21 will be described below. The anode layer 10 is the same layer as the base layer 9.

### -p Type Base Layer 9

dopant: boron, peak impurity concentration: 1.0×10¹⁶ to 1.0×10¹⁸ atoms/cm³, depth: deeper than the emitter layer 7 and shallower than the semiconductor layer 11

### -n Type Semiconductor Layer 11

dopant: arsenic, phosphorus, peak impurity concentration: 1.0×10¹⁵ to 1.0×10¹⁷ atoms/cm³, depth: deeper than the base layer 9 by 0.5 to 1.0 μm
   -n⁺ Emitter Layer 7
dopant: arsenic, phosphorus, peak impurity concentration: 1.0×10¹⁸ to 1.0×10²¹ atoms/cm³, depth: 0.2 to 1.0 μm
   -p⁺ Type Semiconductor Layer 8
dopant: boron, surface impurity concentration: 1.0×10¹⁸ to 1.0×10²¹ atoms/cm³, depth: same as or deeper than the emitter layer 7,
   -Trench Depth D_{trench}: 2.0 μm to Depth Deeper than the Semiconductor Layer 11

### -n Type Buffer Layer 16

dopant: proton, peak impurity concentration C_{P, n2n}≤0.01×C_{P, n1}, depth X_{j, nb2}: X_{j, n2}+20 to 30 μm

### -n Type Buffer Layer 17

dopant: arsenic, phosphorus, peak impurity concentration C_{P, n1}≤1.0×10¹⁵ to 5.0×10¹⁶ atoms/cm³, depth X_{j, n1}: 1.0 to 30 μm

### -p Type Collector Layer 18

dopant: boron, peak impurity concentration: 1.0×10¹⁶ to 1.0×10²⁰ atoms/cm³, depth: 0.3 to 0.8 μm
   -n⁺ Cathode Layer 19
dopant: As, phosphorus, peak impurity concentration: 1.0×10¹⁷ to 1.0×10¹⁹ atoms/cm³, depth: 0.3 to 0.5 μm

The semiconductor device 100 in FIG. 22 is different from the semiconductor device 100 in FIG. 21 in that the semiconductor layer 8 does not exist. Accordingly, the anode layer 10 contacts the first electrode 5. The other configuration is the same as the configuration of the semiconductor device 100 in FIG. 21. In the semiconductor device 100 in FIG. 22, the efficiency of hole implantation from the base layer 9 in the “on” state of a diode included in the RC-IGBT can be decreased as compared to the semiconductor device 100 in FIG. 21.

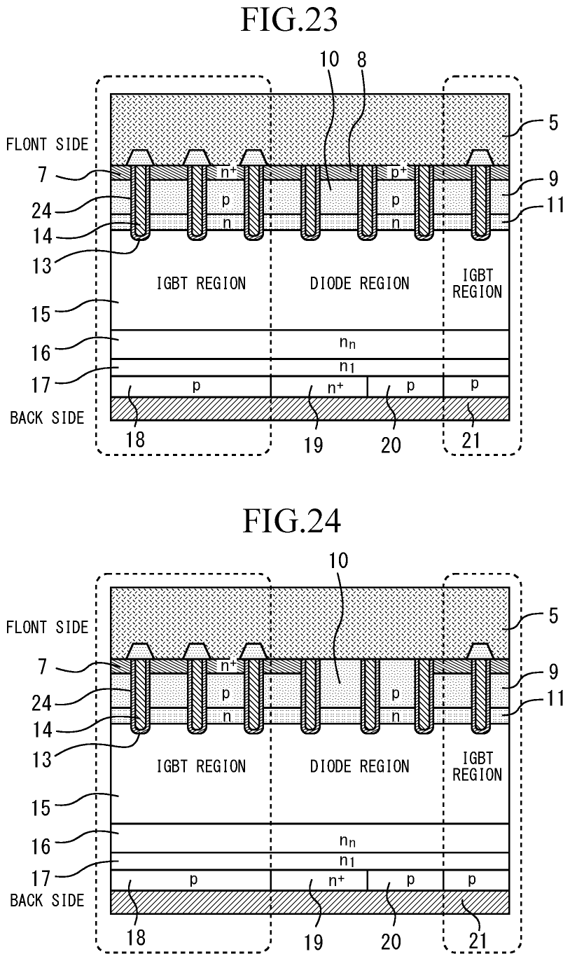

FIG. 23 illustrates a configuration in which a structure on the first surface side is the same as in the semiconductor device 100 in FIG. 21 and the cathode layer 20 is provided. The p type cathode layer 20 is provided on the second surface side of the buffer layer 17 and arranged alongside the n type cathode layer 19 in the direction along the second surface. FIG. 24 illustrates a configuration in which a structure on the first surface side is the same as in the semiconductor device 100 in FIG. 22 and the cathode layer 20 is provided.

### -p Type Cathode Layer 20

dopant: boron, peak impurity concentration: 1.0×10¹⁶ to 1.0×10¹⁸ atoms/cm³, depth: 0.3 to 0.5 μm

In the semiconductor devices 100 in FIGS. 23 and 24, the efficiency of electron implantation from the back side in the “on” state of a diode included in the RC-IGBT can be decreased as compared to the semiconductor devices 100 in FIGS. 21 and 22, respectively.

In the RC-IGBTs in FIGS. 22 to 24, performance on the high speed side on a trade-off curve of a turn-off loss E_{REC} and an “ON” voltage V_{F} in the diode area can be achieved without carrier lifetime control with charged particles such as an electron beam. The performance on the high speed side means performance with low E_{REC} and high V_{F}. Adverse influence of impurity such as oxygen and carbon in an MCZ wafer on diode performance becomes significant when carrier lifetime control with charged particles is performed. The structures in FIGS. 22 to 24 with which the performance on the high speed side on the E_{REC} vs. V_{F} trade-off curve can be improved without cater lifetime control are effective for fully utilizing the MCZ wafer.

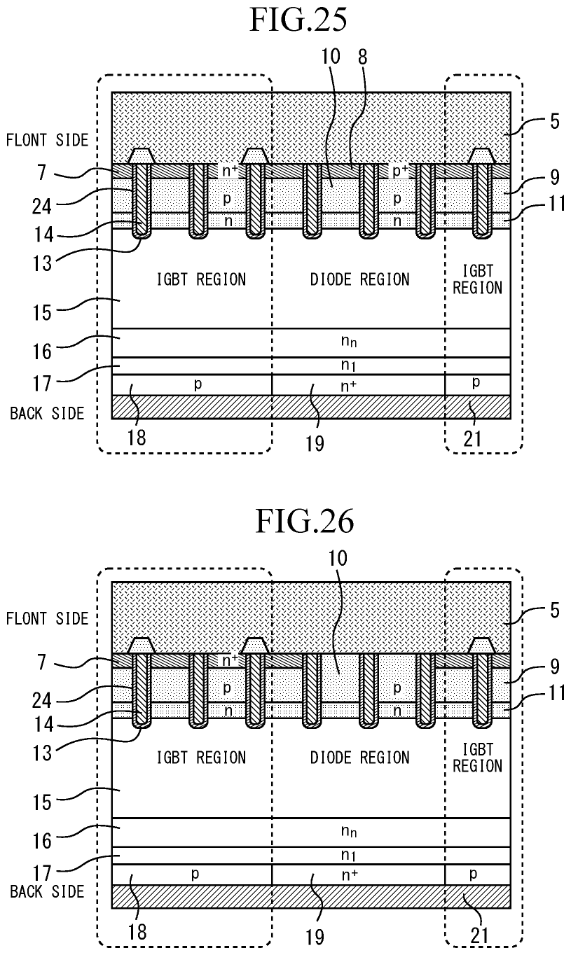

The semiconductor devices 100 in FIGS. 25 to 28 are different from the semiconductor devices 100 in FIGS. 21 to 24, respectively, in that some of a plurality of gate electrodes 14 in the IGBT area contact the first electrode 5. Specifically, the gate electrodes 14 in some of the plurality of trenches 24 are equipotential to the emitter potential. In an RC-IGBT as well, by using a MOS transistor structure, it is possible to achieve reduction of the saturated current density of an IGBT and reduction of oscillation in a no-load short-circuit state by control of capacitance characteristics. Accordingly, it is possible to achieve low “ON” voltage through improvement of the short-circuit resistance amount and improvement of carrier concentration on the emitter side.

Meanwhile, technical features explained in each embodiment may be appropriately combined to use.

Hereinafter, various aspects of the present disclosure will be collectively described as appendixes.

### (Appendix 1)

A semiconductor device comprising:
a silicon substrate having a first surface and a second surface opposite the first surface and containing oxygen as impurity;
a first electrode provided on the first surface; and
a second electrode provided on the second surface,
wherein the silicon substrate includes
   an n type drift layer having impurity concentration that is higher on the second surface side,
   an n type first buffer layer provided on the second surface side of the drift layer and containing protons as impurity, and
   a second buffer layer provided on the second surface side of the first buffer layer.

### (Appendix 2)

The semiconductor device according to appendix 1, wherein the impurity concentration of the drift layer continuously increases from a part at which the drift layer is joined to a layer provided on the first surface side of the drift layer to a part at which the drift layer is joined to the first buffer layer.

### (Appendix 3)

The semiconductor device according to appendix 1 or 2, wherein
the drift layer contains phosphorus or antimony as impurity, and
the second buffer layer contains arsenic or phosphorus as impurity.

### (Appendix 4)

The semiconductor device according to any one of appendixes 1 to 3, wherein oxygen concentration Oᵢ of the drift layer satisfies

$$\\ 1. \times {10}^{17} ln ( {C}_{n} ) - 2.84 \times {10}^{18} \leq {O}_{i} \leq 9.4 \times {10}^{16} ln ( {C}_{n} ) - 2.27 \times {10}^{18}$$

where Cₙ represents the impurity concentration of the drift layer.

### (Appendix 5)

The semiconductor device according to any one of appendixes 1 to 4, wherein
the first buffer layer has impurity concentration with a plurality of peaks in a thickness direction of the silicon substrate, and
the impurity concentration at the plurality of peaks increases as a position is closer to the second buffer layer.

### (Appendix 6)

The semiconductor device according to any one of appendixes 1 to 5, comprising:
a p type base layer provided on the first surface side of the drift layer;
an n type emitter layer provided on the first surface side of the base layer;
a gate electrode provided inside a trench formed on the first surface of the silicon substrate and penetrating through the emitter layer and the base layer; and
a p type collector layer provided on the second surface side of the second buffer layer.

### (Appendix 7)

The semiconductor device according to appendix 6, further comprising an n type semiconductor layer formed deeper than the base layer on the first surface side of the drift layer.

### (Appendix 8)

The semiconductor device according to any one of appendixes 1 to 7, comprising:
a p type anode layer provided on the first surface side of the drift layer; and
an n type cathode layer provided on the second surface side of the second buffer layer.

### (Appendix 9)

The semiconductor device according to appendix 8, comprising a p type cathode layer provided on the second surface side of the second buffer layer and arranged alongside the n type cathode layer in a direction along the second surface.

### (Appendix 10)

The semiconductor device according to any one of appendixes 1 to 5, wherein the silicon substrate has an IGBT area and a diode area.

### (Appendix 11)

The semiconductor device according to appendix 10, wherein the diode area includes
a p type anode layer provided on the first surface side of the drift layer,
an n type cathode layer provided on the second surface side of the second buffer layer, and
an impurity diffusion layer provided on the first surface side of the anode layer and having impurity concentration higher than impurity concentration of the anode layer.

### (Appendix 12)

The semiconductor device according to appendix 10, wherein
the diode area includes
   a p type anode layer provided on the first surface side of the drift layer, and
   an n type cathode layer provided on the second surface side of the second buffer layer, and
the anode layer contacts the first electrode.

### (Appendix 13)

The semiconductor device according to appendix 10, wherein the diode area includes
a p type anode layer provided on the first surface side of the drift layer,
an n type cathode layer provided on the second surface side of the second buffer layer, and
a p type cathode layer provided on the second surface side of the second buffer layer and arranged alongside the n type cathode layer in a direction along the second surface.

### (Appendix 14)

The semiconductor device according to any one of appendixes 10 to 13, wherein
the IGBT area includes
   a p type base layer provided on the first surface side of the drift layer,
   an n type emitter layer provided on the first surface side of the base layer,
   a plurality of gate electrodes provided inside a plurality of trenches formed on the first surface of the silicon substrate and penetrating through the emitter layer and the base layer, and
   a p type collector layer provided on the second surface side of the second buffer layer, and
some of the plurality of gate electrodes contact the first electrode.

### (Appendix 15)

The semiconductor device according to any one of appendixes 10 to 13, wherein
the IGBT area includes
   a p type base layer provided on the first surface side of the drift layer, and
   an n type semiconductor layer formed deeper than the base layer on the first surface side of the drift layer, and
the diode area includes
   a p type anode layer provided on the first surface side of the drift layer, and
   an n type semiconductor layer formed deeper than the anode layer on the first surface side of the drift layer.

### (Appendix 16)

A method of manufacturing a semiconductor device, comprising:
forming a semiconductor layer on a first surface side of a silicon wafer manufactured by an MCZ method and including an n type drift layer;
forming a second buffer layer by performing ion implantation into a second surface opposite the first surface of the silicon wafer and performing annealing;
implanting protons to a position deeper than the second buffer layer with respect to the second surface after the second buffer layer is formed; and
forming a first buffer layer by performing annealing for the protons after the protons are implanted.

### (Appendix 17)

The method of manufacturing a semiconductor device according to appendix 16, comprising forming at least one of a p type layer and an n type layer shallower than the second buffer layer by performing ion implantation into the second surface and performing annealing before performing the annealing for the protons after the protons are implanted.

### (Appendix 18)

The method of manufacturing a semiconductor device according to appendix 16 or 17, wherein
ion implantation is performed a plurality of times to implant the protons, and
the plurality of times of ion implantation are performed with conditions in descending order of acceleration energy and in a smaller dose amount as the acceleration energy increases.

### (Appendix 19)

The method of manufacturing a semiconductor device according to any one of appendixes 16 to 18, wherein the second buffer layer contains arsenic or phosphorus as impurity.

### (Appendix 20)

The method of manufacturing a semiconductor device according to any one of appendixes 16 to 19, wherein the drift layer contains antimony as impurity.

### (Appendix 21)

The method of manufacturing a semiconductor device according to any one of appendixes 16 to 20, wherein the annealing for the protons is performed for 90 minutes or longer at 375 to 425° C.

In a semiconductor device and a method of manufacturing a semiconductor device according to the present disclosure, the impurity profile of a drift layer can be formed by combining a silicon substrate containing oxygen as impurity or a silicon wafer manufactured by an MCZ method with an n type first buffer layer containing protons as impurity. Thus, it is possible to reduce degradation of characteristics such as MOS transistor characteristics.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2023-062638, filed on Apr. 7, 2023 including specification, claims, drawings and summary, on which the Convention priority of the present application is based, are incorporated herein by reference in its entirety.

1. A semiconductor device comprising:
a silicon substrate having a first surface and a second surface opposite the first surface and containing oxygen as impurity;
a first electrode provided on the first surface; and
a second electrode provided on the second surface,
wherein the silicon substrate includes
an n type drift layer having impurity concentration that is higher on the second surface side,
an n type first buffer layer provided on the second surface side of the drift layer and containing protons as impurity, and
a second buffer layer provided on the second surface side of the first buffer layer.

2. The semiconductor device according to claim 1, wherein the impurity concentration of the drift layer continuously increases from a part at which the drift layer is joined to a layer provided on the first surface side of the drift layer to a part at which the drift layer is joined to the first buffer layer.

3. The semiconductor device according to claim 1, wherein
the drift layer contains phosphorus or antimony as impurity, and
the second buffer layer contains arsenic or phosphorus as impurity.

4. The semiconductor device according to claim 1, wherein oxygen concentration Oᵢ of the drift layer satisfies
1.00×10¹⁷ ln(Cₙ)−2.84×10¹⁸≤Oᵢ≤9.40×10¹⁶ ln(Cₙ)−2.27×10¹⁸
where Cₙ represents the impurity concentration of the drift layer.

5. The semiconductor device according to claim 1, wherein
the first buffer layer has impurity concentration with a plurality of peaks in a thickness direction of the silicon substrate, and
the impurity concentration at the plurality of peaks increases as a position is closer to the second buffer layer.

6. The semiconductor device according to claim 1, comprising:
a p type base layer provided on the first surface side of the drift layer;
an n type emitter layer provided on the first surface side of the base layer;
a gate electrode provided inside a trench formed on the first surface of the silicon substrate and penetrating through the emitter layer and the base layer; and
a p type collector layer provided on the second surface side of the second buffer layer.

7. The semiconductor device according to claim 6, further comprising an n type semiconductor layer formed deeper than the base layer on the first surface side of the drift layer.

8. The semiconductor device according to claim 1, comprising:
a p type anode layer provided on the first surface side of the drift layer; and
an n type cathode layer provided on the second surface side of the second buffer layer.

9. The semiconductor device according to claim 8, comprising a p type cathode layer provided on the second surface side of the second buffer layer and arranged alongside the n type cathode layer in a direction along the second surface.

10. The semiconductor device according to claim 1, wherein the silicon substrate has an IGBT area and a diode area.

11. The semiconductor device according to claim 10, wherein the diode area includes
a p type anode layer provided on the first surface side of the drift layer,
an n type cathode layer provided on the second surface side of the second buffer layer, and
an impurity diffusion layer provided on the first surface side of the anode layer and having impurity concentration higher than impurity concentration of the anode layer.

12. The semiconductor device according to claim 10, wherein
the diode area includes
a p type anode layer provided on the first surface side of the drift layer, and
an n type cathode layer provided on the second surface side of the second buffer layer, and
the anode layer contacts the first electrode.

13. The semiconductor device according to claim 10, wherein the diode area includes
a p type anode layer provided on the first surface side of the drift layer,
an n type cathode layer provided on the second surface side of the second buffer layer, and
a p type cathode layer provided on the second surface side of the second buffer layer and arranged alongside the n type cathode layer in a direction along the second surface.

14. The semiconductor device according to claim 10, wherein
the IGBT area includes
a p type base layer provided on the first surface side of the drift layer,
an n type emitter layer provided on the first surface side of the base layer,
a plurality of gate electrodes provided inside a plurality of trenches formed on the first surface of the silicon substrate and penetrating through the emitter layer and the base layer, and
a p type collector layer provided on the second surface side of the second buffer layer, and
some of the plurality of gate electrodes contact the first electrode.

15. The semiconductor device according to claim 10, wherein
the IGBT area includes
a p type base layer provided on the first surface side of the drift layer, and
an n type semiconductor layer formed deeper than the base layer on the first surface side of the drift layer, and
the diode area includes
a p type anode layer provided on the first surface side of the drift layer, and
an n type semiconductor layer formed deeper than the anode layer on the first surface side of the drift layer.

16. A method of manufacturing a semiconductor device, comprising:
forming a semiconductor layer on a first surface side of a silicon wafer manufactured by an MCZ method and including an n type drift layer;
forming a second buffer layer by performing ion implantation into a second surface opposite the first surface of the silicon wafer and performing annealing;
implanting protons to a position deeper than the second buffer layer with respect to the second surface after the second buffer layer is formed; and
forming a first buffer layer by performing annealing for the protons after the protons are implanted.

17. The method of manufacturing a semiconductor device according to claim 16, comprising forming at least one of a p type layer and an n type layer shallower than the second buffer layer by performing ion implantation into the second surface and performing annealing before performing the annealing for the protons after the protons are implanted.

18. The method of manufacturing a semiconductor device according to claim 16, wherein
ion implantation is performed a plurality of times to implant the protons, and
the plurality of times of ion implantation are performed with conditions in descending order of acceleration energy and in a smaller dose amount as the acceleration energy increases.

19. The method of manufacturing a semiconductor device according to claim 16, wherein the second buffer layer contains arsenic or phosphorus as impurity.

20. The method of manufacturing a semiconductor device according to claim 16, wherein the drift layer contains antimony as impurity.

21. The method of manufacturing a semiconductor device according to claim 16, wherein the annealing for the protons is performed for 90 minutes or longer at 375 to 425° C.
